(19) United States
(12) Patent Application Publication
(10) Pub. No.: US 2016/0372456 A1
(43) Pub. Date: Dec. 22, 2016

(54) SEMICONDUCTOR DEVICE HAVING AN ELECTROSTATIC DISCHARGE PROTECTION CIRCUIT

(71) Applicant: Samsung Electronics Co., Ltd., Suwon-si (KR)

(72) Inventors: Jae-Hyun Yoo, Suwon-si (KR); Jong-Sung JEON, Hwaseong-si (KR)

(73) Assignee: Samsung Electronics Co., Ltd., Suwon-si (KR)

(21) Appl. No.: 15/155,361

(22) Filed: May 16, 2016

(30) Foreign Application Priority Data
Jun. 19, 2015 (KR) 10-2015-0087168

(51) Int. Cl. H01L 27/02; H01L 29/06

(52) U.S. Cl. CPC H01L 27/0266; H01L 29/0642; H01L 29/0684

(57) ABSTRACT

A semiconductor device includes a first well in a substrate, a gate structure on the first well, a second well below the gate structure in the first well, a third well in a first side of the gate structure and in the first well to be adjacent to the second well, the third well having a conductivity type different from that of the second well, a fourth well overlapped with the third well, a fifth well in a second side of the gate structure and in the second well, a sixth well below the gate structure and in the second well, the sixth well being adjacent to the fifth well and having an impurity concentration higher than the impurity concentration of the second well, and a first device isolation layer overlapped with the second well and disposed farther away from the gate structure than the fifth well.

### CROSS-REFERENCE TO RELATED APPLICATION

This application claims priority from Korean Patent Application No. 10-2015-0087168, filed on Jun. 19, 2015, in the Korean Intellectual Property Office, the disclosure of which is incorporated herein by reference in its entirety.

### BACKGROUND

1. Field of the Invention

The present inventive concepts relate to a semiconductor device having an electrostatic discharge (hereinafter, referred to as ESD) protection circuit.

2. Description of the Related Art

Recent semiconductor devices have been developed in a way that they able to operate at high speed, and a degree of integration in a process of manufacturing semiconductor devices has been increased.

In addition, in accordance with the miniaturization and refinement of semiconductor devices, the ESD phenomenon significantly influences operational properties of the devices. Thus, research into various technologies for mitigating or preventing such electrostatic discharge has been conducted.

In particular, in a high voltage IC application in a high voltage region, ESD solutions for individual components need to be provided and thus, the necessity of improving ESD properties has increased.

### SUMMARY

An aspect of the present inventive concepts may provide a semiconductor device having improved reliability while allowing for a high-voltage ESD operation.

However, aspects of the present inventive concepts are not restricted to the one set forth herein. The above and other aspects of the present inventive concepts will become more apparent to one of ordinary skill in the art to which the present inventive concepts pertain by referencing the detailed description of the present inventive concepts given below.

According to an aspect of the present inventive concepts, there is provided a semiconductor device including a first well in a substrate, a gate structure on the first well, a second well below the gate structure in the first well, a third well in a first side of the gate structure and in the first well to be adjacent to the second well, the third well having a conductivity type different from that of the second well, a fourth well overlapped with the third well, a fifth well in a second side of the gate structure and in the second well, a sixth well below the gate structure and in the second well, the sixth well being adjacent to the fifth well and having an impurity concentration higher than the impurity concentration of the second well, and a first device isolation layer overlapped with the second well and disposed farther away from the gate structure than the fifth well.

In some embodiments, the semiconductor device may further include a second device isolation layer in the sixth well. The second device isolation layer may be formed below the gate structure to be overlapped with the gate structure.

In some embodiments, the second device isolation layer may be formed deeper than the fifth well.

In some embodiments, the second device isolation layer may be spaced apart from the fourth well.

In some embodiments, the semiconductor device may further include an eighth well overlapped with the second device isolation layer and having an impurity concentration higher than the impurity concentration of the sixth well.

In some embodiments, the eighth well may be not overlapped with the gate structure and be positioned between the gate structure and the fifth well.

In some embodiments, the semiconductor device may further include an eighth well in the sixth well and having an impurity concentration higher than the impurity concentration of the sixth well.

In some embodiments, the second well may have a conductivity type different from that of the first well, and the fifth well may have a conductivity type different from that of the second well.

According to an aspect of the present inventive concepts, there is provided another semiconductor device including a first well in a substrate, a second well in the first well, the second well having a conductivity type different from that of the first well, a first well structure on the second well, a second gate structure on the second well and spaced apart from the first gate structure, a third well between the first and second gate structures and in the second well, a fourth well in a first side of the first and second gate structures and in the second well, a fifth well in a second side of the first and second gate structures and in the second well, a sixth well below the first gate structure and spaced apart from the third well while being adjacent to the fourth well, the sixth well having a conductivity type different from that of the fourth well, and a seventh well below the second gate structure and spaced apart from the third well while being adjacent to the fifth well, the seventh well having a conductivity type different from that of the fifth well.

In some embodiments, the semiconductor device may further include a first device isolation layer overlapped with the second well and disposed farther away from the first gate structure than the fourth well, and a second device isolation layer overlapped with the second well and disposed farther away from the second gate structure than the fifth well.

In some embodiments, the semiconductor device may further include an eighth well between the first device isolation layer and the fourth well and in the second well, wherein the eighth well is disposed to be adjacent to the fourth well, the eighth well having a conductivity type different from that of the fourth well.

In some embodiments, the semiconductor device may further include a third device isolation layer in the sixth well and a fourth device isolation layer in the seventh well.

In some embodiments, the semiconductor device may further include a ninth well overlapped with the third device isolation layer and having an impurity concentration higher than that of the sixth well.

In some embodiments, the semiconductor device may further include a ninth well formed in the sixth well and having an impurity concentration higher than that of the sixth well.

In some embodiments, each of the third well fourth well may have a conductivity type different from that of the second well, and the first well may contain an n-type impurity.

According to an aspect of the present inventive concepts, there is provided still another semiconductor device semiconductor device including a first well in a substrate, a second well in the first well, a first gate structure on the second well, a second gate structure on the second well, the second gate structure being spaced apart from the first gate structure, a third well in a first side of the first and second gate structures and in the first well to be adjacent to the second well, the third well having a conductivity type different from that of the second well, a fourth well in a second side of the first and second gate structures and in the first well to be adjacent to the second well, the fourth well having a conductivity type different from that of the second well, a fifth well between the first and second gate structures and in the second well, a sixth well between the first gate structure and the fifth well, the sixth well having a conductivity type different from that of the fifth well, a seventh well between the second gate structure and the fifth well, the seventh well having a conductivity type different from that of the fifth well, an eighth well overlapped with the third well, a ninth well overlapped with the fourth well, a tenth well disposed below the first gate structure and spaced apart from the eighth well while being adjacent to the sixth well, the tenth well having a conductivity type different from that of the sixth well, and an eleventh well disposed below the second gate structure and spaced apart from the ninth well while being adjacent to the seventh well, the eleventh well having a conductivity type different from that of the seventh well.

In some embodiments, the semiconductor device may further include a first device isolation layer in the tenth well, and a second device isolation layer in the eleventh well.

In some embodiments, the semiconductor device may further include a twelfth well in the tenth well and having an impurity concentration higher than in the impurity concentration of the sixth well

### BRIEF DESCRIPTION OF DRAWINGS

FIG. 1 is a layout diagram of a semiconductor device according to a first example embodiment of the present inventive concepts.

FIG. 2 is a cross-sectional view taken along line A-A of FIG. 1.

FIG. 3 is a view illustrating an operation of the semiconductor device according to the first example embodiment of the present inventive concepts.

FIG. 4 is a cross-sectional view of a semiconductor device according to a second example embodiment of the present inventive concepts.

FIG. 5 is a cross-sectional view of a semiconductor device according to a third example embodiment of the present inventive concepts.

FIG. 6 is a cross-sectional view of a semiconductor device according to a fourth example embodiment of the present inventive concepts.

FIG. 7 is a layout diagram of a semiconductor device according to a fifth example embodiment of the present inventive concepts.

FIG. 8 is a cross-sectional view taken along line B-B of FIG. 7.

FIG. 9 is a view illustrating an operation of a semiconductor device according to a sixth example embodiment of the present inventive concepts.

FIG. 10 is a cross-sectional view of a semiconductor device according to a seventh example embodiment of the present inventive concepts.

FIG. 11 is a cross-sectional view of a semiconductor device according to an eighth example embodiment of the present inventive concepts.

FIG. 12 is a layout diagram of a semiconductor device according to a ninth example embodiment of the present inventive concepts.

FIG. 13 is a cross-sectional view taken along line C-C of FIG, 12.

FIG. 14 is a view illustrating an operation of the semiconductor device according to the ninth example embodiment of the present inventive concepts.

FIG. 15 is a cross-sectional view of a semiconductor device according to a tenth example embodiment of the present inventive concepts.

FIG. 16 is a cross-sectional view of a semiconductor device according to an eleventh example embodiment of the present inventive concepts.

FIG. 17 is a cross-sectional view of a semiconductor device according to a twelfth example embodiment of the present inventive concepts.

FIG. 18 is a block diagram illustrating an ESD protection circuit including a semiconductor device according to some example embodiments of the present inventive concepts.

FIG. 19 is a view illustrating a semiconductor device according to some other example embodiments of the present inventive concepts.

FIG. 20 is a view illustrating a semiconductor device according to some other example embodiments of the present inventive concepts.

FIG. 21 is a block diagram illustrating a wireless communications device including the semiconductor device according to the example embodiments of the present inventive concepts.

FIG. 22 is a block diagram of a computing system including the semiconductor device according to the example embodiments of the present inventive concepts.

FIG. 23 is a block diagram of an electronic system including the semiconductor device according to the example embodiments of the present inventive concepts.

FIG. 24 through FIG. 26 are example semiconductor systems to which the semiconductor device according to some example embodiments of the present inventive concepts are applicable.

### DETAILED DESCRIPTION

Advantages and features of the present inventive concepts and methods of accomplishing the same may be understood more readily by reference to the following detailed description of example embodiments and the accompanying drawings. The present inventive concepts may, however, be embodied in many different forms and should not be construed as being limited to the embodiments set forth herein. Rather, these embodiments are provided so that this disclosure will be thorough and complete and will fully convey the concepts of the inventive concepts to those skilled in the art, and the present inventive concepts will only be defined by the appended claims. In the drawings, the thickness of layers and regions are exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concepts (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concepts.

The present inventive concepts will be described with reference to perspective views, cross-sectional views, and/or plan views, in which example embodiments of the inventive concepts are shown. Thus, the profile of an example view may be modified according to manufacturing techniques and/or allowances. That is, the embodiments of the inventive concepts are not intended to limit the scope of the present inventive concepts but cover all changes and modifications that can be caused due to a change in manufacturing process. Thus, regions shown in the drawings are illustrated in schematic form and the shapes of the regions are presented simply by way of illustration and not as a limitation.

Unless defined otherwise, all technical and scientific terms used herein have the same meaning as commonly understood by one of ordinary skill in the art to which this inventive concepts belong. It is noted that the use of any and all examples, or example terms provided herein is intended merely to better illuminate the inventive concepts and is not a limitation on the scope of the inventive concepts unless otherwise specified. Further, unless defined otherwise, all terms defined in generally used dictionaries may not be overly interpreted.

In concluding the detailed description, those skilled in the art will appreciate that many variations and modifications can be made to the example embodiments without substantially departing from the principles of the present inventive concepts. Therefore, the disclosed example embodiments of the inventive concepts are used in a generic and descriptive sense only and not for purposes of limitation.

In general, semiconductor devices are very sensitively affected by high voltage introduced from electrostatic discharge (or static electricity) occurring from the outside. In the case that high voltage is temporarily introduced into a chip due to such electrostatic discharge (ESD, hereinafter, referred to as ‘ESD’), the introduced high voltage may break a thin insulating film, a channel or the like formed within an integrated circuit, thereby breaking the chip itself. Thus, in order to protect the interior of a chip from such external ESD, semiconductor devices may have an ESD power clamp circuit and an ESD protection circuit, embedded in each pad thereof to which an external signal is received.

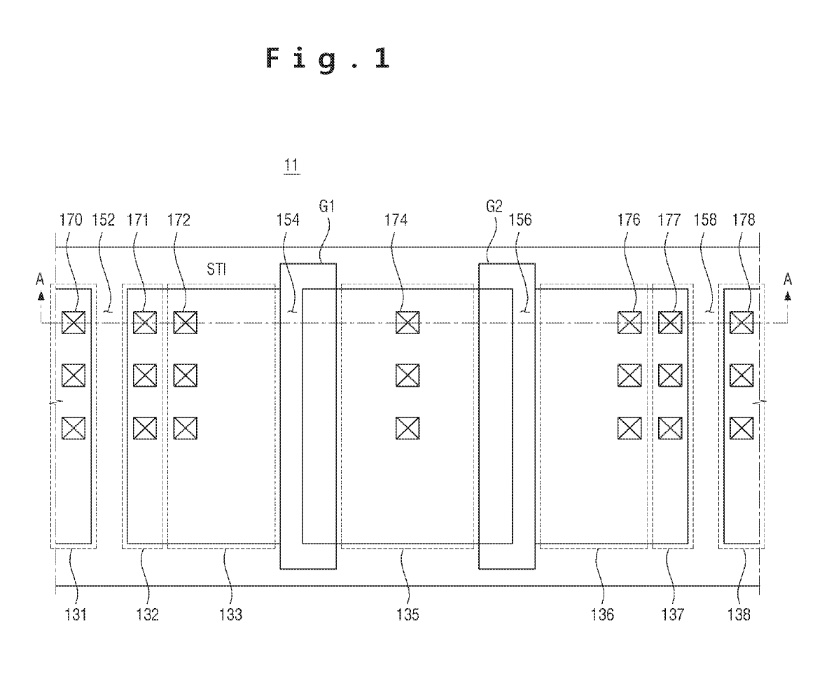

Hereinafter, semiconductor devices according to some example embodiments of the present inventive concepts will be described with reference to FIG. 1 through FIG. 26.

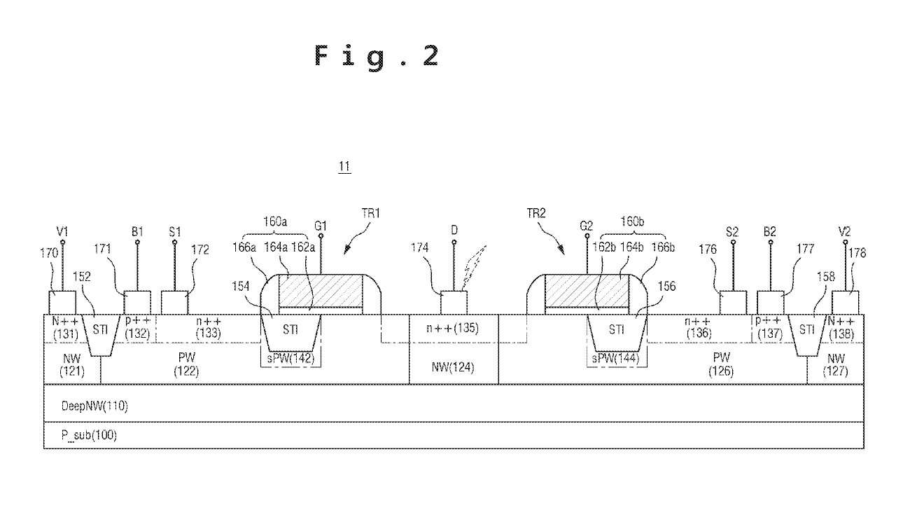

FIG. 1 is a layout diagram of a semiconductor device according to a first example embodiment of the present inventive concepts. FIG. 2 is a cross-sectional view taken along line A-A of FIG. 1. FIG, 3 is a view illustrating an operation of the semiconductor device according to the first example embodiment of the present inventive concepts,

Referring to FIG. 1 through FIG. 3, a semiconductor device 11 according to the first example embodiment of the present inventive concepts may include a substrate 100, a first well 110, a second well 122, a third well 124, a fourth well 135, a fifth well 133, a sixth well 142, a seventh well 132, an eleventh well 121, a twelfth well 131, a first gate structure 160a, a second gate structure 160b, a first device isolation layer 152, a second device isolation layer 154, a first electrode 174, a second electrode 172, a third electrode 170 and a fourth electrode 171.

The substrate 100 may be, for example, bulk silicon or a silicon-on insulator (SOI). Unlike this, the substrate 100 may be a silicon substrate or may contain another material, for example, silicon germanium, indium antimonide, a lead telluride compound, indium arsenide, indium phosphide, gallium arsenide, or gallium antimonide.

Alternatively, the substrate 100 may include an epitaxial layer formed on a base substrate. In this case, the epitaxial layer may contain, for example, silicon or germanium, an elemental semiconductor material. In addition, the epitaxial layer may contain a compound semiconductor, for example, a group IV-IV compound semiconductor or a group III-V compound semiconductor.

Specifically, the group IV-IV compound semiconductor may be formed of, for example, a binary compound or a ternary compound containing at least two or more of carbon (C), silicon (Si), germanium (Ge) and tin (Sn), or a compound containing the said compound doped with a group IV element.

The group III-V compound semiconductor may be formed of a binary compound, a ternary compound, or a quaternary compound, formed by combining at least one of aluminum (Al), (Ga) and indium (In) as a group III element with one of phosphorus (P), arsenic (As) and antimony (Sb) as a group V element.

As illustrated in the example embodiment, the substrate 100 may be, for example, a p-type substrate, but the present inventive concepts are inventive concepts are not limited thereto.

The first well 110 may be formed in the substrate 100. The first well 110 may be formed over the entire surface of the substrate 100 as illustrated in the example embodiment of the present inventive concepts.

A conductivity type of the first well 110 may be different from t e substrate 100. That is, when the substrate 100 is a p-type substrate, the first well 110 may be an n-type well. However, the present inventive concepts are not limited thereto, and conductive types of the substrate 100 and the first well 110 may be modified without limitation.

The first gate structure 160a may be formed on the first well 110. The first gate structure 160a may include a gate insulating layer 162a, again electrode 164a, and a spacer 166a. The second gate structure 160b may be formed substantially identically to the first gate structure 160a and hereinafter, a description will be made based on the first gate structure 160a.

Specifically, the gate insulating layer 162a may be formed between the substrate 100 and the gate electrode 164a. The gate insulating layer 162a may include a high-K layer. In the case that the gate insulating layer 162a is a high-K layer, the gate insulating layer 162a may be formed of a material having a high dielectric constant. In some example embodiments of the present inventive concepts, the material having a high dielectric constant may be, for example, HfO2, Al2O3, ZrO2, TaO2 or the like, but the present inventive concepts are not limited thereto,

Although not illustrated in detail, between the gate insulating layer 162a and the substrate 100, an interface layer (not shown) serving to mitigate or prevent interface defects between the gate insulating layer 162a and the substrate 100 may be further disposed. The interface layer (not shown) may contain a low dielectric layer, a dielectric constant (k) of which is equal to or less than 9, for example, a silicon oxide layer (k is about 4) or a silicon oxynitride (k is about 4 to 8 according to the contents of oxygen atoms and nitrogen atoms). Alternatively, the interface layer (not shown) may be formed of silicate and may be formed of combinations of the layers exemplified as above.

The gate electrode 164a may contain a conductive material. In some example embodiments of the present inventive concepts, the gate electrode 164a may contain high conductive metal, but the present inventive concepts are not limited thereto. That is, in some other example embodiments of the present inventive concepts, the gate electrode 164a may be formed of non-metal such as polysilicon. For example, the gate electrode 164a may be formed of Si, SiGe or the like, which is non-metal. The gate electrode 164a may be formed, for example, through a replacement process, but is not limited thereto.

The spacer 166a may be disposed on at least one side of the gate electrode 164a. Specifically, as illustrated in FIG. 2, the spacer 166a may be disposed on both sides of the gate electrode 164a. The spacer 166a may contain at least one of a nitride layer and an oxynitride layer. FIG. 2 illustrates a case in which one side of the spacer 166a is curved, but the present inventive concepts are not limited thereto. Unlike the shape illustrated in FIG. 2, a shape of the spacer 166a may be modified without limitation. For example, in some example embodiments of the present inventive concepts, the shape of the spacer 166a may be modified into an I-shape, an L-shape or the like, unlike the illustrated shape.

The second well 122 may be disposed below the first gate structure 160a and formed in the first well 110. A conductivity type of the second well 122 may be different from that of the first well 110. For example, when the first well 110 is an n-type well, the second well 122 may be a p-type well. However, the present inventive concepts are not limited thereto, and conductive types of the first well 110 and the second well 122 may be modified without limitation.

The third well 124 may be disposed in one side of the gate structure and may be formed in the first well 110 to be adjacent to the second well 122. Specifically, a lower surface of the third well 124 may be positioned coplanar with a lower surface of the second well 122. A side surface of the third well 124 may be adjacent to a side surface of the second well 122. A conductivity type of the third well 124 may be different from that of the second well 122 and may be identical to that of the first well 110. For example, when the second well 122 is a p-type well, the third well 124 may be an n-type well and the first well 110 may also be an n-type well, but the present inventive concepts are not limited thereto.

The fourth well 135 may be formed to be overlapped with the third well 124. Specifically, the fourth well 135 may be overlapped with an upper portion of the third well 124. In addition, an upper portion of the second well 122 may be partially overlapped with the fourth well 135. The fourth well 135 may be disposed in one side of the first gate structure 160a. A conductivity type of the fourth well 135 may be identical to that of the third well 124. For example, when the third well 124 is an n-type well, the fourth well 135 may be an n-type well. However, a concentration of an impurity contained in the fourth well 135 may he higher than that of an impurity contained in the third well 124. During an operation of the semiconductor device according to the example embodiment, the fourth well 135 may be used as a drain region, for example, but the present inventive concepts are not limited thereto.

The first electrode 174 may be disposed on the fourth well 135 and may be electrically connected to the fourth well 135. For example, the first electrode 174 may be connected to a drain terminal but the present inventive concepts are not limited thereto.

The fifth well 133 may be formed in the second well 122. Specifically, the upper portion of the second well 122 may be partially overlapped with the fifth well 133. The fifth well 133 may be disposed in the other side of the first gate structure 160a. That is, the fifth well 133 and the fourth well 135 may be disposed in both sides of the first gate structure 160a.

A conductivity type of the fifth well 133 may be identical to that of the fourth well 135. In addition, the conductivity type of the fifth well 133 may be different from that of the second well 122. For example, when the second well 122 is a p-type well, the fifth well 133 may be an n-type well. A concentration of an impurity contained in the fifth well 133 may be higher than that of an impurity contained in the second well 122. During the operation of the semiconductor device according to the example embodiment, the fifth well 133 may be used as a source region, for example, but the present inventive concepts are not limited thereto.

The second electrode 172 may be disposed on the fifth well 133 and may be electrically connected to the fifth well 133. For example, the second electrode 172 may be connected to a source terminal but the present inventive concepts are not limited thereto.

The sixth well 142 may be disposed below the first gate structure 160a and may be formed in the second well 122 to be adjacent to the fifth well 133. In addition, the sixth well 142 may be spaced apart from the fourth well 135. The sixth well 142 may be formed in a portion of a channel disposed below the first gate structure 160a. The sixth well 142 may be overlapped with only a portion of the first gate structure 160a. That is, the sixth well 142 may be only disposed below a portion of the first gate structure 160a.

The sixth well 142 may be formed deeper than the fifth well 133. A conductivity type of the sixth well 142 may be different from that of the fifth well 133. In addition, the conductivity type of the sixth well 142 may be identical to that of the second well 122. For example, when the second well 122 is a p-type well, the sixth well 142 may be a p-type well.

A concentration of an impurity contained in the sixth well 142 may be higher than that of an impurity contained in the second well 122. Accordingly, a flow of electrons introduced into the fifth well 133 may be formed in the circumference of the sixth well 142 having an impurity concentration higher than that in the surroundings thereof or may be formed below the sixth well 142, and a detailed description thereof will be described later.

The first device isolation layer 152 may be formed to be overlapped with the second well 122 and may be disposed farther away from the gate structure than the fifth well 133. Specifically, one portion of the first device isolation layer 152 may be formed to be overlapped with the second well 122, and the other portion of the first device isolation layer 152 may be adjacent to the eleventh well 121 adjacent to the second well 122, a conductivity type of the eleventh well 121 being different from that of the second well 122. That is, the first device isolation layer 152 may be formed between the second well 122 and the eleventh well 121, but the present inventive concepts are not limited thereto.

The first device isolation layer 152 may be formed to have a shallow trench isolation (STI) structure advantageous to high degrees of integration due to superior isolation properties and a small occupied area thereof, but is not limited thereto. The device isolation layer may contain, for example, at least one of a silicon oxide, a silicon nitride, a silicon oxynitride and combinations thereof. FIG. 2 illustrates a case in which a cross-sectional shape of the first device isolation layer 152 is tapered, but the present inventive concepts are not limited to the illustrated shape. That is, the cross-sectional shape of the device isolation layer may be modified without limitation, if necessary.

The eleventh well 121 may be formed substantially, identically to the third well 124, and may be formed in the first well 110 to be adjacent to the second well 122 and the first device isolation layer 152. The conductivity type of the eleventh well may be different from that of the second well 122.

The twelfth well 131 may be formed on the eleventh well 121. The twelfth well 131 may be adjacent to the first device isolation layer 152 and may be formed substantially, identically to the fourth well 135.

The third electrode 170 may be disposed on the twelfth well 131 and may be electrically connected to the twelfth well 131. For example, the third electrode 170 may be connected to a drain terminal, a VDD terminal, and an ISO terminal, but the present inventive concepts are not limited thereto.

The seventh well 132 may be positioned between the first device isolation layer 152 and the fifth well 133 and may be formed in the second well 122. The seventh well 132 may be disposed to be adjacent to the first device isolation layer 152 and the fifth well 133, a conductivity type of the seventh well 132 being different from that of the fifth well 133. For example, when the fifth well 133 is an n-type well, the seventh well 132 may be a p-type well. However, a concentration of an impurity contained in the seventh well 132 may be higher than that of an impurity contained in the second well 122. During the operation of the semiconductor device according to the example embodiment, the seventh well 132 may be used as a base region of a pNPN (parasitic NPN) transistor, for example, but the present inventive concepts are not limited thereto.

The fourth electrode 171 may be disposed on the seventh well 132 and may be electrically connected to the seventh well 132. For example, the fourth electrode 171 may be connected to aground terminal, but the present inventive concepts are not limited thereto.

The second device isolation layer 154 may be formed in the sixth well 142. Specifically, the second device isolation layer 154 may be formed below the first gate structure 160a to be overlapped with the first gate structure 160a. The second device isolation layer 154 may be formed only below the first gate structure 160a. In addition, the second device isolation layer 154 may be formed only in the sixth well 142, but the present inventive concepts are not limited thereto.

The second device isolation layer 154 may be formed deeper than the fifth well 133. That is, a lower surface of the second device isolation layer 154 may be lower than a lower surface of the fifth well 133. The second device isolation layer 154 may be spaced apart from the fourth well 135.

The second device isolation layer 154 may be formed to have a shallow trench isolation (STI) structure advantageous to high degrees of integration due to superior isolation properties and a small occupied area thereof, but is not limited thereto. The device isolation layer may contain, for example, at least one of a silicon oxide, a silicon nitride, a silicon nitride and combinations thereof. FIG. 2 illustrates a case in which a cross-sectional shape of the second device isolation layer 154 is tapered, but the present inventive concepts are not limited to the illustrated shape. That is, the cross-sectional shape of the device isolation layer may be modified without limitation, if necessary.

As illustrated in FIG. 2, the first gate structure 160a and the second gate structure 160b may be formed to be symmetrical to each other with respect to the third well 124. Based on the third well 124, components (for example, the second well 122 to the seventh well 132, the eleventh well 121, the twelfth well 131, and the first and second device isolation layers 154) disposed on the left and components (reference numerals 126, 127, 136, 137, 138, 144, 156 and 158) disposed on the right so as to be symmetrical to the left components with respect to the third well 124 may be formed substantially, identically to each other and therefore, a detailed description thereof will be omitted.

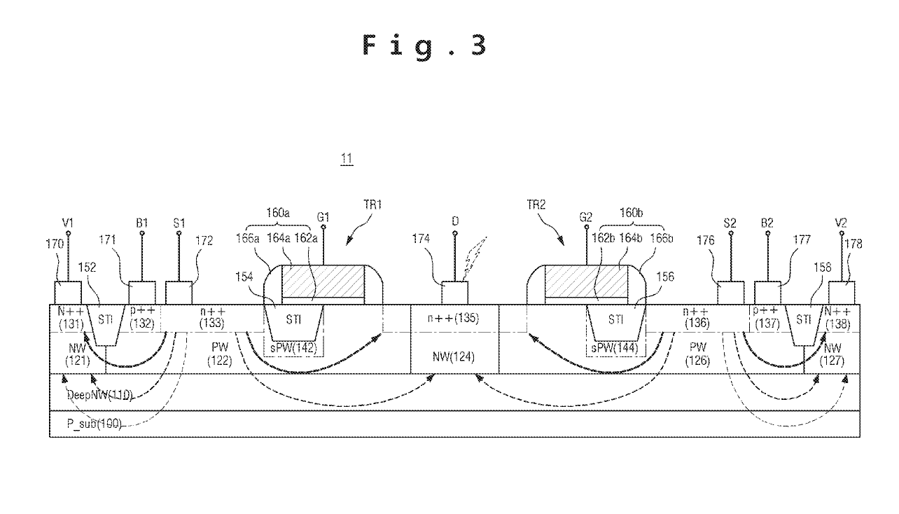

Referring to FIG. 3, the semiconductor device according to the example embodiment of the present inventive concepts may include a first transistor TR1 and a second transistor TR2, the first transistor TR1 and the second transistor TR2 being operated as ESD devices. Hereinafter, a description will be made based on the first transistor TR1.

The first transistor TR1 may include the first gate structure 160a, and the fourth well 135 disposed in one side of the first gate structure 160a may be operated as a drain region and the fifth well 133 may be operated as a source region. In addition, the twelfth well 131 may be operated as a drain region or a VDD region. High voltage ESD may be introduced into the drain region.

As described above, the first transistor TR1 according to the present inventive concepts may include the first device isolation layer 152 and the second device isolation layer 154, and the first device isolation layer 152 and the second device isolation layer 154 may form an isolated STI region in gate and source regions. The isolated STI region may vertically form a deep current path directed from the drain region (for example, the fourth well 135 or the twelfth well 131) to the source region (for example, the fifth well 133) so as to be close to the substrate 100.

In addition, the sixth well 142 may be formed below the first gate structure 160a and the conductivity type of the sixth well 142 may be different from that of the source region or the drain region. Moreover, the sixth well 142 may be disposed to be adjacent to the source region, while being spaced apart from the drain region, hut the present inventive concepts are not limited thereto. For example, the sixth well 142 may be a shallow PW (Spw). Further, the second device isolation layer 154 may be formed in the sixth well 142. By doing so, a path of electrons moving from the source region to the drain region may be directed more downward and through STI interfacial effects and the like, the concentration of a current flow on a channel interface may be mitigated or prevented.

Furthermore, deep n-type wells (NW) such as the third well 124 and the eleventh well 121 may be periodically formed to form a new current path. By doing so, the current path may be further deeply formed, such that existing current characteristics may be improved.

In addition, the seventh well 132 may be disposed to be adjacent to the fifth well 133 operated as the source region, and a conductivity type of the seventh well 132 may be different from that of the fifth well 133, whereby the parasitic transistor pNPN may be independently operated. By doing so, uniformity in the current flow may be improved.

Moreover, in the semiconductor device according to the example embodiment of the present inventive concepts, the source region may be formed similarly to the drain region, such that vertical properties with respect to the current flow of the semiconductor device may be further improved.

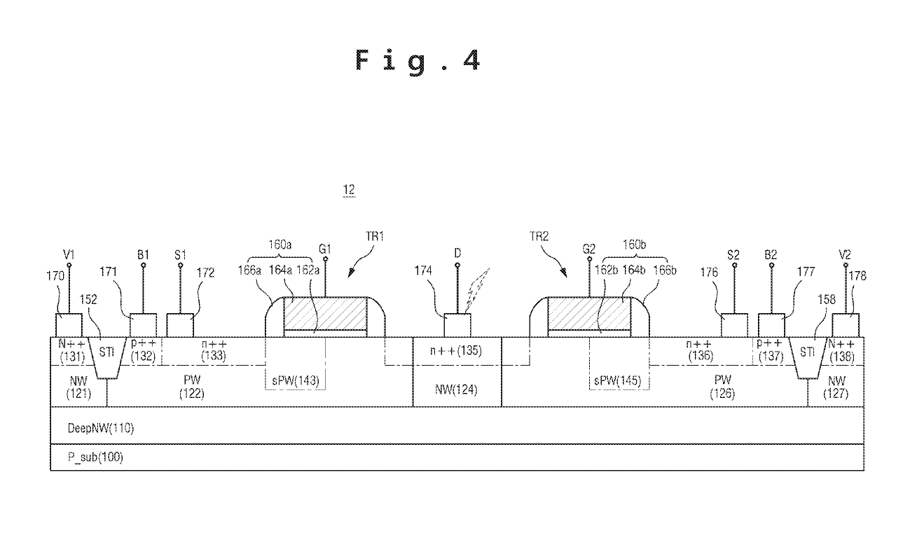

FIG. 4 is a cross-sectional view of a semiconductor device according to a second example embodiment of the present inventive concepts. For convenience of explanation, an overlapped description regarding elements identical to those of the foregoing embodiment will be omitted, and differences will be mainly explained hereinafter.

Referring to FIG. 4, a semiconductor device 12 according to the second example embodiment of the present inventive concepts may be formed and operated in a manner substantially identical to that of the semiconductor device 11 according to the first example embodiment of the present inventive concepts described with reference to FIG. 2.

However, in the semiconductor device 12 according to the second example embodiment of the present inventive concepts, the second device isolation layer 154 may not be formed. As the second device isolation layer 154 is not formed, a channel region of the first transistor TR1 may be operated.

By doing so, while the semiconductor device 11 according to the first example embodiment of the present inventive concepts are usable only as a gate-grounded (GG) type device, the semiconductor device 12 according to the second example embodiment of the present inventive concepts may be used as a gate-coupled (GC) type device as well as being used as the GG type device.

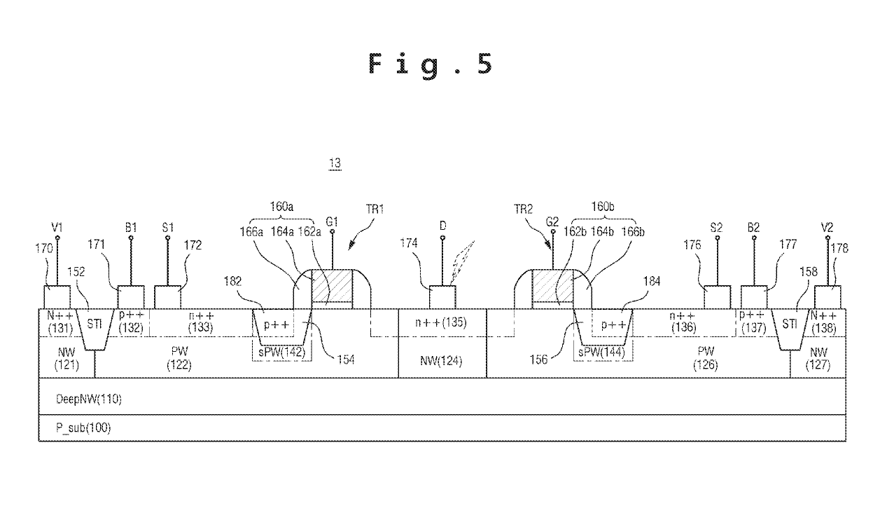

FIG. 5 is a cross-sectional view of a semiconductor device according to a third example embodiment of the present inventive concepts. For convenience of explanation, an overlapped description regarding elements identical to those of the foregoing embodiments will be omitted, and differences will be mainly explained hereinafter.

Referring to FIG. 5, a semiconductor device 13 according to the third example embodiment of the present inventive concepts may be formed and operated in a manner substantially identical to that of the semiconductor device 11 according to the first example embodiment of the present inventive concepts described with reference to FIG. 2.

However, the semiconductor device 13 according to the third example embodiment of the present inventive concepts may further include an eighth well 182. The eighth well 182 may be formed in the sixth well 142. In addition, the eighth well 182 may be overlapped with the second device isolation layer 154.

Specifically, an upper portion of the second device isolation layer 154 may be partially overlapped with the eighth well 182. In addition, the eighth well 182 may be overlapped with a portion of the sixth well 142. The eighth well 182 may be disposed in the other side of the first gate structure 160a. That is, the eighth well 182 and the fourth well 135 may be disposed in both sides of the first gate structure 160a. Moreover, the eighth well 182 may be positioned between the first gate structure 160a and the fifth well 133 and may be disposed not to be overlapped with the first gate structure 160a. However, the present inventive concepts are not limited thereto.

A conductivity type of the eighth well 182 may be identical to that of the sixth well 142. In addition, the conductivity type of the eighth well 182 may be different from that of the fifth well 133. For example, when the sixth well 142 is a p-type well, the eighth well 182 may be a p-type well. A concentration of an impurity contained in the eighth well 182 may be higher than that of an impurity contained in the sixth well 142. The eighth well 182 may be formed by additionally doping a p-type impurity into the second device isolation layer 154 exposed, but the present inventive concepts are not limited thereto.

By doing so, a path of electrons moving from the source region to the drain region may be directed more downward and due to STI interfacial effects and the formation of a new current path, the concentration of a current flow on a channel interface may be mitigated or prevented.

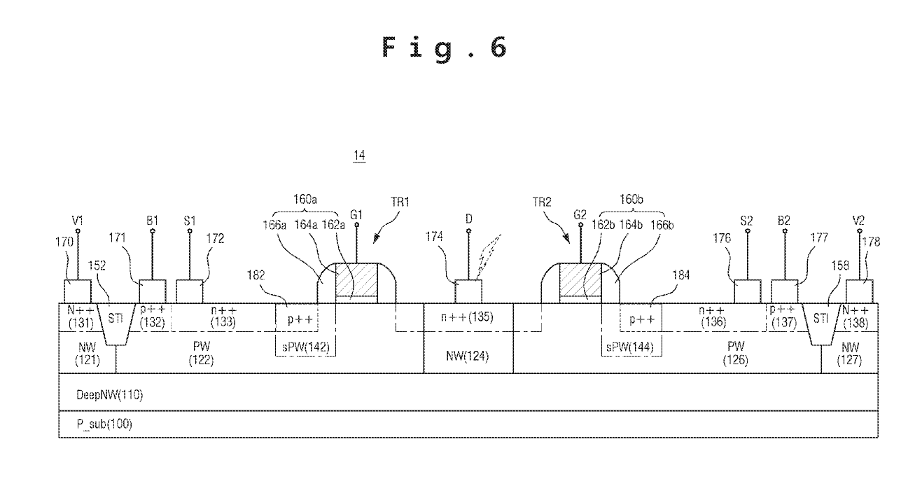

FIG. 6 is a cross-sectional view of a semiconductor device according to a fourth example embodiment of the present inventive concepts. For convenience of explanation, an overlapped description regarding elements identical to those of the foregoing embodiments will be omitted, and differences will be mainly explained hereinafter.

Referring to FIG. 6, a semiconductor device 14 according to the fourth example embodiment of the present inventive concepts may be formed and operated in a manner substantially identical to that of the semiconductor device 12 according to the second example embodiment of the present inventive concepts described with reference to FIG. 4.

However, the semiconductor device 14 according to the fourth example embodiment of the present inventive concepts may further include the eighth well 182. Consequently, the second device isolation layer 154 may not be formed in the sixth well 142, and only the eighth well 182 may be formed therein.

Specifically, the eighth well 182 may be formed in the sixth well 142. Specifically, an upper portion of the sixth well 142 may be partially overlapped with the eighth well 182. The eighth well 182 may be disposed in the other side of the first gate structure 160a. That is, the eighth well 182 and the fourth well 135 may be disposed in both sides of the first gate structure 160a. Moreover, the eighth well 182 may be positioned between the first gate structure 160a and the fifth well 133 and may be disposed not to be overlapped with the first gate structure 160a.

The eighth well 182 may be formed by additionally doping a p-type impurity into the sixth well 142 exposed. The conductivity type of the eighth well 182 may be identical to that of the sixth well 142. In addition, the conductivity type of the eighth well 182 may be different from that of the fifth well 133. For example, when the sixth well 142 is a p-type well, the eighth well 182 may be a p-type well. The concentration of an impurity contained in the eighth well 182 may be higher than that of an impurity contained in the sixth well 142. By doing so, a path of electrons moving from the source region to the drain region may be formed downwardly of the eighth well 182 and the sixth well 142, such that the concentration of a current flow on a channel interface may be mitigated or prevented.

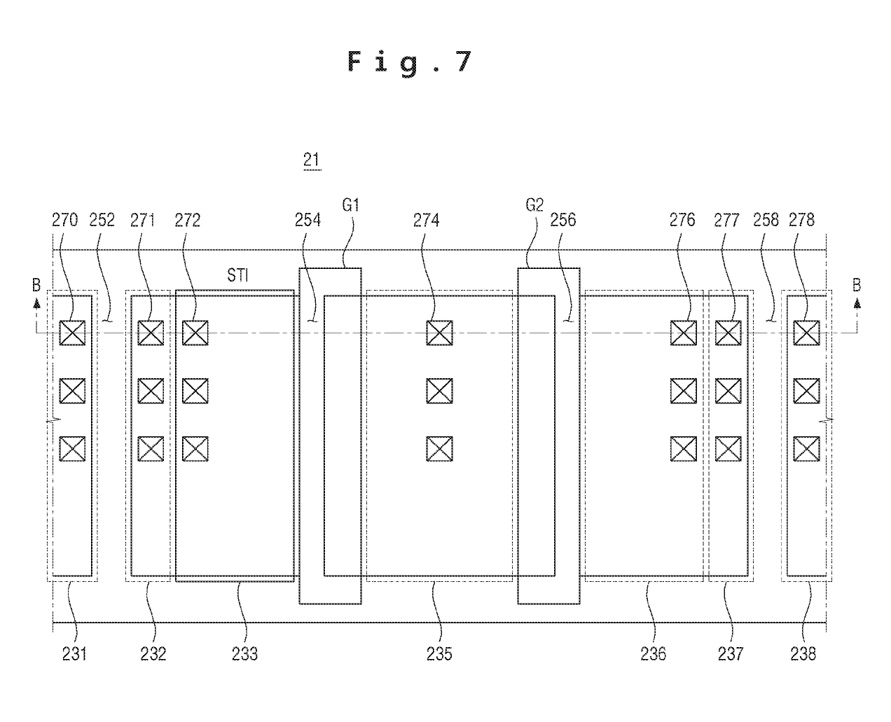

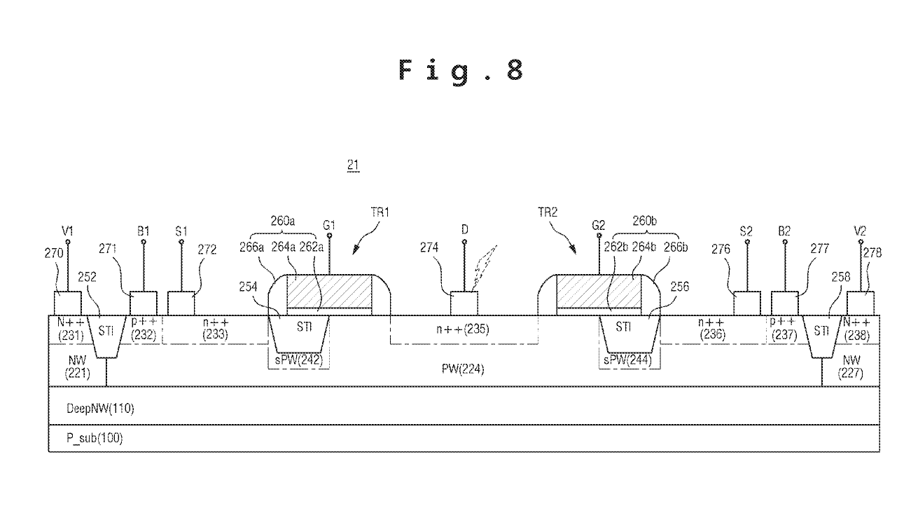

FIG. 7 is a layout diagram of a semiconductor device according to a fifth example embodiment of the present inventive concepts, FIG. 8 is a cross-sectional view taken along line B-B of FIG. 7.

Referring to FIG. 7 and FIG. 8, a semiconductor device 21 according to the fifth example embodiment of the present inventive concepts may include the substrate 100, the first well 110, a second well 224, a third well 235, a fourth well 233, a fifth well 236, a sixth well 242, a seventh well 244, an eighth well 232, an eleventh well 221, a twelfth well 231, a first gate structure 260a, a second gate structure 260b, first to fourth device isolation layers 252, 254, 256, and 258, a first electrode 274, a second electrode 272, a third electrode 270 and a fourth electrode 271.

The substrate 100 may be, for example, bulk silicon or a silicon-on insulator (SOI). Unlike this, the substrate 100 may be a silicon substrate or may contain another material, for example, silicon germanium, indium antimonide, a lead telluride compound, indium arsenide, indium phosphide, gallium arsenide, or gallium antimonide.

Alternatively, the substrate 100 may include an epitaxial layer formed on a base substrate. In this case, the epitaxial layer may contain, for example, silicon or germanium, an elemental semiconductor material. In addition, the epitaxial layer may contain a compound semiconductor, for example, a group compound semiconductor or a group III-V compound semiconductor.

As illustrated in the example embodiment, the substrate 100 may be, for example, a p-type substrate 100, but the present inventive concepts are not limited thereto.

The first well 110 may be formed in the substrate 100. The first well 110 may be formed over the entire surface of the substrate 100 as illustrated in the example embodiment of the present inventive concepts.

A conductivity type of the first well 110 may be different from that of the substrate 100. That is, when the substrate 100 is a p-type substrate, the first well 110 may be an n-type well. However, the present inventive concepts are not limited thereto, and conductive types of the substrate 100 and the first well 110 may be modified without limitation.

The first gate structure 260a and the second gate structure 260b may be formed on the first well 110. The first gate structure 260a may include a gate insulating layer 262a, a gate electrode 264a, and a spacer 266a.

The second gate structure 260b may be formed on the second well 224 to be spaced apart from the first gate structure 260a. The second gate structure 260b may be formed substantially, identically to the first gate structure 260a. Since the first gate structure 260a and the second gate structure 260b may be formed substantially, identically to the first gate structure 160a and the second gate structure 160b included in the semiconductor device 11 according to the first example embodiment, a detailed description thereof will be omitted.

The second well 224 may be disposed below the first gate structure 260a and the second gate structure 260b and may be formed in the first well 110. A conductivity type of the second well 224 may be different from that of the first well 110. For example, when the first well 110 is an n-type well, the second well 224 may be a p-type well. However, the present inventive concepts are not limited thereto, and conductive types of the first well 110 and the second well 224 may be modified without limitation.

The third well 235 may be positioned between the first gate structure 260a and the second gate structure 260b and may be formed in the second well 224. The third well 235 may be adjacent to only the second well 224 but may be spaced apart from the first well 110. A conductivity type of the third well 235 may be different from that of the second well 224 and may be identical to that of the first well 110. For example, when the second well 224 is a p-type well, the third well 235 may be an n-type well and the first well 110 may also be an n-type well. However, the present inventive concepts are not limited thereto.

However, a concentration of an impurity contained in the third well 235 may be higher than that of an impurity contained in the second well 224. During an operation of the semiconductor device according to the example embodiment of the present inventive concepts, the third well 235 may be used as a common drain region of a first transistor TR1 and a second Transistor TR2, but the present inventive concepts are not limited thereto.

The first electrode 274 may be disposed on the third well 235 and may be electrically connected to the third well 235. For example, the first electrode 274 may be connected to a common drain terminal of the first transistor TR1 and the second transistor TR2, but the present inventive concepts are not limited thereto.

The fourth well 233 may be disposed in one side of the first and second wire structures 260a and 260b and may be formed in the second well 224. Specifically, the fourth well 233 may be overlapped with an upper portion of the second well 224.

A conductivity type of the fourth well 233 may be identical to that of the third well 235. In addition, the conductivity type of the fourth well 233 may be different from that of the second well 224. For example, when the second well 224 is a p-type well, the fourth well 233 may be an n-type well. However, a concentration of an impurity contained in the fourth well 233 may be higher than that of an impurity contained in the second well 224. During the operation of the semiconductor device according to the example embodiment, be fourth well 233 may be used as a source region of the first transistor TR1, for example, but the present inventive concepts are not limited thereto.

The second electrode 272 may be disposed on the fourth well 233 and may be electrically connected to the fourth well 233. For example, the second electrode 272 may be connected to a source terminal of the first transistor TR1, but the present inventive concepts are not limited thereto.

The fifth well 236 may be disposed in other side of the first and second gate structures 260a and 260b and may be formed in the second well 224. Specifically, the upper portion of the second well 224 may be partially overlapped with the fifth well 236. The fifth well 236 may be formed substantially, identically to the fourth well 233. For example, the fifth well 236 may be operated as a source region of the second transistor TR2, but the present inventive concepts are not limited thereto.

The sixth well 242 may be disposed below the first gate structure 260a and may be formed in the second well 224 to be adjacent to the fourth well 233. In addition, the sixth well 242 may be spaced apart from the third well 235. The sixth well 242 may be formed in a portion of a channel disposed below the first gate structure 260a. The sixth well 242 may be overlapped with only a portion of the first gate structure 260a. That is, the sixth well 242 may be only disposed below a portion of the first gate structure 260a.

The sixth well 242 may be formed deeper than the fourth well 233. A conductivity type of the sixth well 242 may be different from that of the fourth well 233. In addition, the conductivity type of the sixth well 242 may be identical to that of the second well 224. For example, when the second well 224 is a p-type well, the sixth well 242 may be a p-type well.

A concentration of an impurity contained in the sixth well 242 may be higher than that of an impurity contained in the second well 224. In addition, the concentration of an impurity contained in the sixth well 242 may be higher than that of an impurity contained in the fourth well 233. Accordingly, a flow of electrons introduced into the fourth well 233 may be formed in the circumference of the sixth well 242 having an impurity concentration higher than that in the surroundings thereof or may be formed below the sixth well 242.

The first device isolation layer 252 may be formed to be overlapped with the second well 224 and may be disposed farther away from the first gate structure 260a than the fourth well 233. Specifically, one portion of the first device isolation layer 252 may be formed to be overlapped with the second well 224, and the other portion of the first device isolation layer 252 may be adjacent to the eleventh well 221 adjacent to the second well 224, a conductivity type of the eleventh well 221 being different from that of the second well 224. That is, the first device isolation layer 252 may be formed between the second well 224 and the eleventh well 221, but the present inventive concepts are not limited thereto. The second device isolation layer 258 may be formed to be overlapped with the second well 4 and may be disposed farther away from the second gate structure 260b than the fifth well 236.

The eleventh well 221 may be formed in the first well 110 to be adjacent to the second well 4 and the first device isolation layer 252. The conductivity type of the eleventh well 221 may be different from that of the second well 224. A lower surface of the eleventh well 221 may be positioned coplanar with a lower surface of the second well 224, but is not limited thereto.

The twelfth well 231 may be formed on the eleventh well 221. The twelfth well 231 may be adjacent to the first device isolation layer 252 and may be formed substantially, identically to the fourth well 233.

The third electrode 270 may be disposed on the twelfth well 231 and may be electrically connected to the twelfth well 231. For example, the third electrode 270 may be connected to a drain terminal, a VDD terminal, and an ISO terminal, but the present inventive concepts are not limited thereto.

The seventh well 244 may be disposed below the second gate structure 260b and may be formed in the second well 224 to be adjacent to the fifth well 236. In addition, the seventh well 244 may be spaced apart from the third well 235. The seventh well 244 may be formed in a portion of a Channel disposed below the second gate structure 260b. The seventh well 244 may be overlapped with only a portion of the second gate structure 260b. That is, the seventh well 244 may be only disposed below a portion of the second gate structure 260b. The seventh well 244 may be formed substantially identically to the sixth well 242.

The eighth well 232 may be positioned between the first device isolation layer 252 and the fourth well 233 and may be formed in the second well 224. The eighth well 232 may be disposed to be adjacent to the first device isolation layer 252 and the fourth well 233, a conductivity type of the eighth well 232 being different from that of the fourth well 233. For example, when the fourth well 233 is an n-type well, the eighth well 232 may be a p-type well. A concentration of an impurity contained in the eighth well 232 may be higher than that of an impurity contained in the second well 224. During the operation of the semiconductor device according to the example embodiment, the eighth well 232 may be used as a base region of a pNPN (parasitic NPN) transistor, for example, but the present inventive concepts are not limited thereto.

The fourth electrode 271 may be disposed on the eighth well 232 and may be electrically connected to the eighth well 232. For example, the fourth electrode 271 may be connected to a ground terminal, but the present inventive concepts are not limited thereto.

The third device isolation layer 254 may be formed in the sixth well 242. Specifically, the third device isolation layer 254 may be formed below the first gate structure 260a to be overlapped with the first gate structure 260a. The third device isolation layer 254 may be formed only below the first gate structure 260a. In addition, the third device isolation layer 254 may be formed only in the sixth well 242, but the present inventive concepts are not limited thereto.

The third device isolation layer 254 may be formed deeper than the fourth well 233. That is, a lower surface of the third device isolation layer 254 may be lower than a lower surface of the fourth well 233. The third device isolation layer 254 may be spaced apart from the third well 235.

The third device isolation layer 254 may be formed to have a shallow trench isolation (STI) structure advantageous to high degrees of integration due to superior isolation properties and a small occupied area thereof, but is not limited thereto. The device isolation layer may contain, for example, at least one of a silicon oxide, a silicon nitride, a silicon oxynitride and combinations thereof. FIG. 2 illustrates a case in which a cross-sectional shape of the third device isolation layer 254 is tapered, but the present inventive concepts are not limited to the illustrated shape. That is, the cross-sectional shape of the device isolation layer may be modified without limitation, if necessary.

The fourth device isolation layer 256 may be formed in the seventh well 244. Since the fourth device isolation layer 256 is formed substantially, identically to the third device isolation layer 254, a detailed description will be omitted.

The semiconductor device 21 according to the fifth example embodiment of the present inventive concepts may be operated in a manner substantially identical to that of the semiconductor device 11 according to the first example embodiment of the present inventive concepts described with reference to FIG, 3. However, the third well 235 of the semiconductor device 21 according to the fifth example embodiment may not be adjacent to the first well 110. Thus, in the semiconductor device 21 according to the fifth example embodiment, the first well 110 and the drain region of the transistor may be short-circuited and thus, the transistor may be usable as an input/output (I/O) transistor. However, the present inventive concepts are not limited thereto.

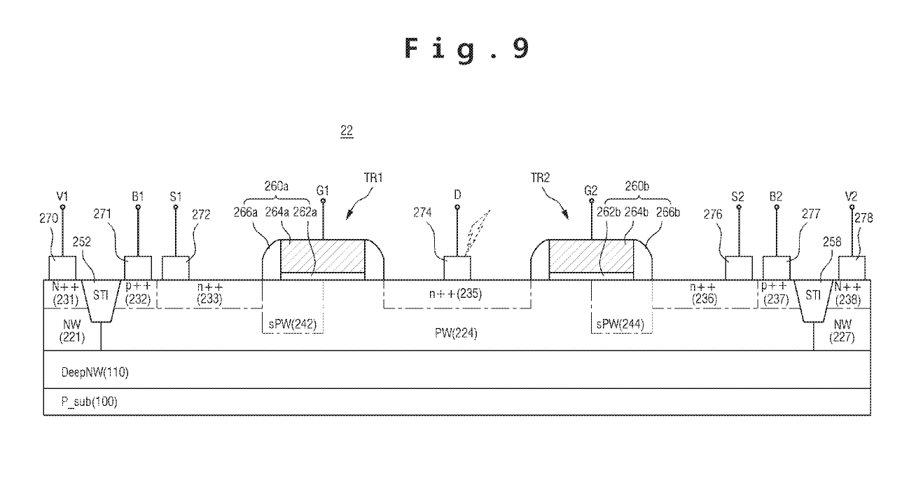

FIG. 9 is a view illustrating an operation of a semiconductor device according to a sixth example embodiment of the present inventive concepts. For convenience of explanation, an overlapped description regarding elements identical to those of the foregoing embodiments will be omitted, and differences will be mainly explained.

Referring to FIG. 9, a semiconductor device 22 according to the sixth example embodiment of the present inventive concepts may be formed and operated in a manner substantially identical to that of the semiconductor device 21 according to the fifth example embodiment of the present inventive concepts described with reference to FIG. 8.

However, in the semiconductor device 22 according to the sixth example embodiment of the present inventive concepts, the third device isolation layer 254 may not be formed. As the third device isolation layer 254 is not formed, a channel region of the first transistor TR1 may be operated.

By doing so, while the semiconductor device 21 according to the fifth example embodiment of the present inventive concepts are usable only as a gate-grounded (GG) type device, the semiconductor device 22 according to the sixth example embodiment of the present inventive concepts may be used as a gate-coupled (GC) type device as well as being used as the GG type device.

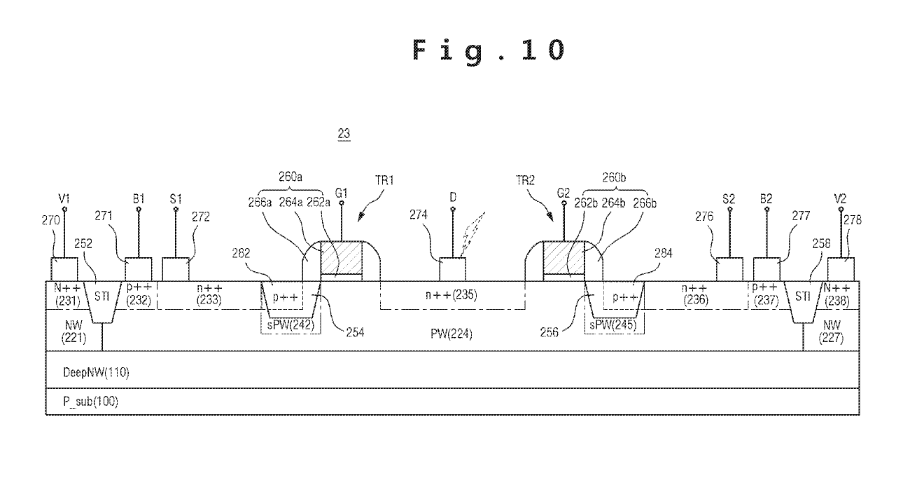

FIG. 10 is a cross-sectional view of a semiconductor device according to a seventh example embodiment of the present inventive concepts. For convenience of explanation, an overlapped description regarding elements identical to those of the foregoing embodiments will be omitted, and differences will be mainly explained.

Referring to FIG. 10, a semiconductor device 23 according to the seventh example embodiment of the present inventive concepts may be formed and operated in a manner substantially identical to that of the semiconductor device 21 according to the fifth example embodiment of the present inventive concepts described with reference to FIG. 8.

However, the semiconductor device 23 according to the seventh example embodiment of the present inventive concepts may further include a ninth well 282. The ninth well 282 may be formed in the sixth well 242, in addition, the ninth well 282 may be overlapped with the third device isolation layer 254.

Specifically, an upper portion of the third device isolation layer 254 may be partially overlapped with the ninth well 282. In addition, the ninth well 282 may be overlapped with a portion of the sixth well 242. The ninth well 282 may be disposed in the other side of the first gate structure 260a. That is, the ninth well 282 and the third well 235 may be disposed in both sides of the first gate structure 260a. Moreover, the ninth well 282 may be positioned between the first gate structure 260a and the fourth well 233 and may be disposed not to be overlapped with the first gate structure 260a. However, the present inventive concepts are not limited thereto.

A conductivity type of the ninth well 282 may be identical to that of the sixth well 242. In addition, the conductivity type of the eighth well 182 may be different from that of the fourth well 233. For example, when the sixth well 242 is a p-type well, the ninth well 282 may be a p-type well. A concentration of an impurity contained in the ninth well 282 may be higher than that of an impurity contained in the sixth well 242. The ninth well 282 may be formed by additionally doping a p-type impurity into the third device isolation layer 254 exposed, but the present inventive concepts are not limited thereto.

An upper portion of the fourth device isolation layer 256 may be partially overlapped with a tenth well 284. In addition, the tenth well 284 may be overlapped with a portion of the seventh well 244. The ninth well 282 and the tenth well 284 may be formed and operated in a substantially identical manner.

By doing so, a path of electrons moving from the source region to the drain region may be directed more downward and due to STI interfacial effects and the formation of a new current path, the concentration of a current flow on a channel interface may be mitigated or prevented.

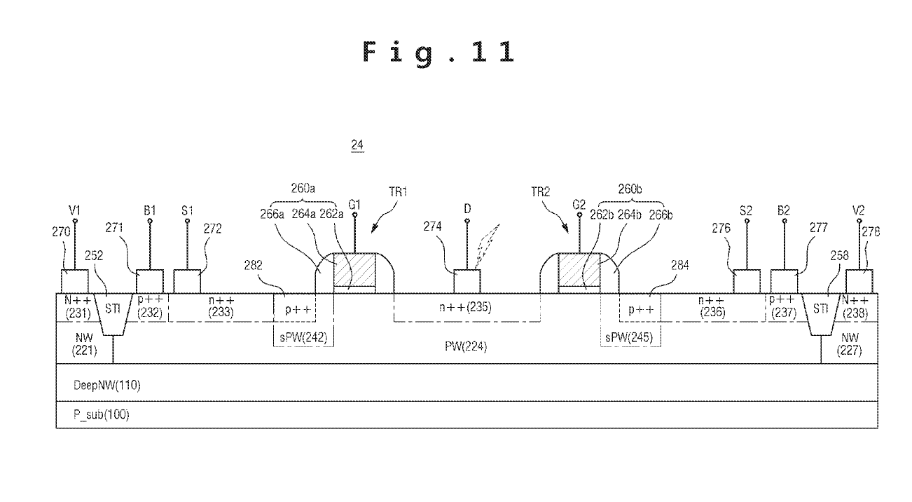

FIG. 11 is a cross-sectional view of a semiconductor device according to an eighth example embodiment of the present inventive concepts. For convenience of explanation, with regard to elements identical to those of the foregoing embodiments, an overlapped description will be omitted and differences will be mainly explained.

Referring to FIG. 11, a semiconductor device 24 according to the eighth example embodiment of the present inventive concepts may be formed and operated in a manner substantially identical to that of the semiconductor device 22 according to the sixth example embodiment of the present inventive concepts described with reference to FIG. 9.

However, the semiconductor device 24 according to the eighth example embodiment of the present inventive concepts may further include the ninth well 282. Consequently, the third device isolation layer 254 may not be formed in the sixth well 242, and only the ninth well 282 may be formed therein.

Specifically, the ninth well 282 may be formed in the sixth well 242. Specifically, an upper portion of the sixth well 242 may be partially overlapped with the ninth well 282. The ninth well 282 may be disposed in the other side of the first gate structure 260a. That is, the ninth well 282 and the fourth well 233 may be disposed in both sides of the first gate structure 260a. Moreover, the ninth well 282 may be positioned between the first gate structure 260a and the fifth well and may be disposed not to be overlapped with the first gate structure 260a.

The ninth well 282 may be formed by additionally doping a p-type impurity into the sixth well 242 exposed. The conductivity type of the ninth well 282 may be identical to that of the sixth well 242. In addition, the conductivity type of the ninth well 282 may be different from that of the fourth well 233. For example, when the sixth well 242 is a p-type well, the ninth well 282 may be a p-type well. The concentration of an impurity contained in the ninth well 282 may be higher than that of an impurity contained in the sixth well 242. By doing so, a path of electrons moving from the source region to the drain region may be formed downwardly of the ninth well 282 and the sixth well 242, such that the concentration of a current flow on a channel interface may be mitigated or prevented.

In a similar manner, the tenth well 284 may be formed in the seventh well 244. Specifically, an upper portion of the seventh well 244 may be partially overlapped with the tenth well 284. The ninth well 282 and the tenth well 284 may be formed and operated in a substantially identical manner.

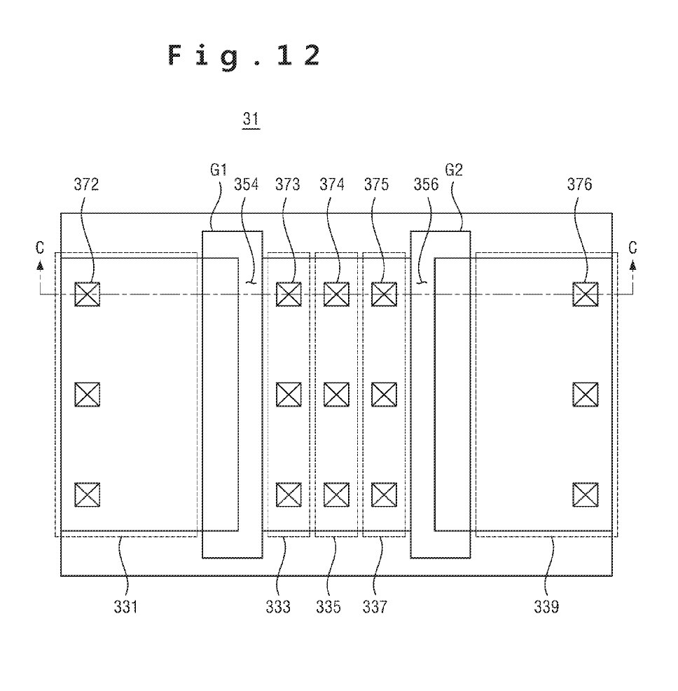

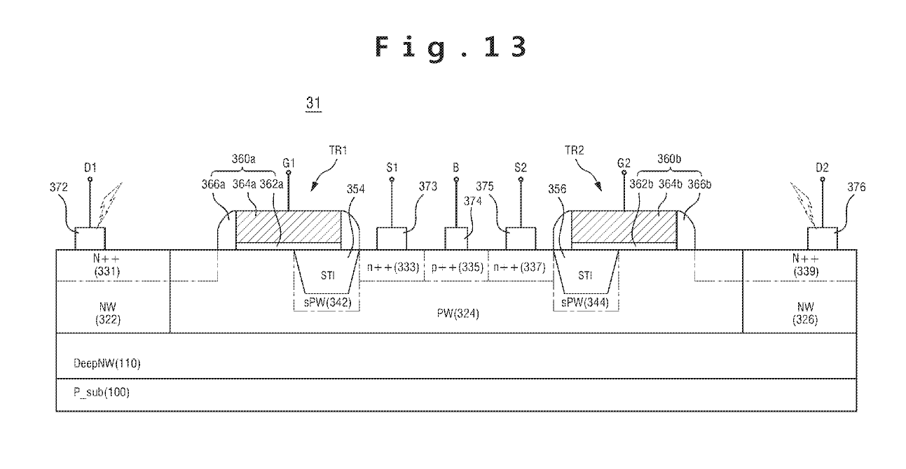

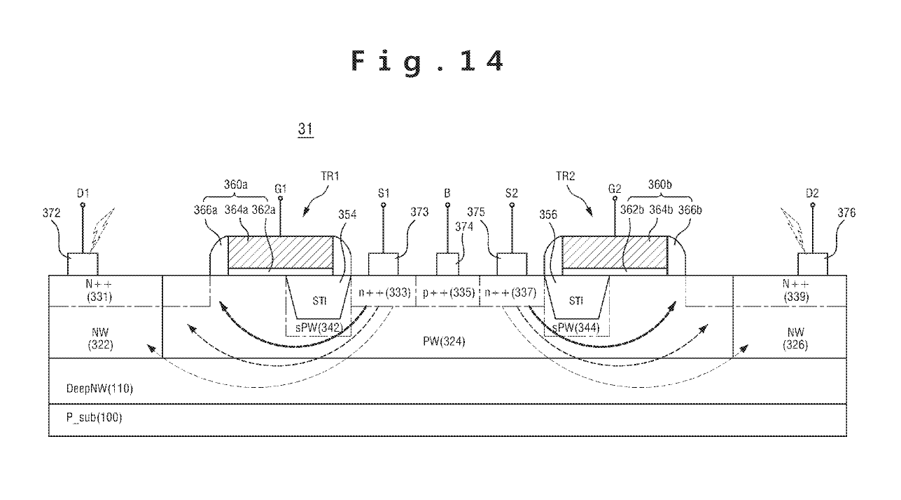

FIG. 12 is a layout diagram of a semiconductor device according to a ninth example embodiment of the present inventive concepts, FIG. 13 is a cross-sectional view taken along line C-C of FIG. 12. FIG. 14 is a view illustrating an operation of the semiconductor device according to the ninth example embodiment of the present inventive concepts. For convenience of explanation, with regard to elements identical to those of the foregoing embodiments, an overlapped description will be omitted and differences will be mainly explained.

Referring to FIG. 12 through FIG. 14, a semiconductor device 31 according to the ninth example embodiment of the present inventive concepts may include the substrate 100, the first well 110, a second well 324, a third well 322, a fourth well 336, a fifth well 335, a sixth well 333, a seventh well 337, an eighth well 331, a ninth well 339, a tenth well 342, an eleventh well 334, a first gate structure 360a, a second gate structure 360b, a first device isolation layer 354, a second device isolation layer 356, a first electrode 374, a second electrode 373, and a third electrode 272.

The substrate 100 may be, for example, bulk silicon or a silicon-on insulator (SOI). Unlike this, the substrate 100 may be a silicon substrate or may contain another material, for example, silicon germanium, indium antimonide, a lead telluride compound, indium arsenide, indium phosphide, gallium arsenide, or gallium antimonide. In the example embodiment, the substrate 100 may be, for example, a p-type substrate, but the present inventive concepts are not limited thereto.

The first well 110 may be formed in the substrate 100. The first well 110 may be formed over the entire surface of the substrate 100 as illustrated in the example embodiment of the present inventive concepts.

A conductivity type of the first well 110 may be different from that of the substrate 100. That is, when the substrate 100 is a p-type substrate, the first well 110 may be an n-type well. However, the present inventive concepts are not limited thereto, and conductive types of the substrate 100 and the first well 110 may be modified without limitation.

The first gate structure 360a and the second gate structure 360b may be formed on the first well 110. The first gate structure 360a may include agate insulating layer 362a, a gate electrode 364a, and a spacer 366a.

The second gate structure 360b may be formed on the second well 324 to be spaced apart from the first gate structure 360a. The second gate structure 360b may be formed substantially, identically to the first gate structure 360a. The first gate structure 360a and the second gate structure 360b may be formed substantially, identically to the first gate structure 160a and the second gate structure 160b included in the semiconductor device 11 according to the first example embodiment.

The second well 324 may be disposed below the first gate structure 360a and the second gate structure 360b and may be formed in the first well 110. A conductivity type of the second well 324 may be different from that of the first well 110. For example, when the first well 110 is an n-type well, the second well 324 may be a p-type well. However, the present inventive concepts are not limited thereto, and conductive types of the first well 110 and the second well 324 may be modified without limitation.

The third well 322 may be disposed in one side of the first gate structure 360a and the second gate structure 360b and may be formed in the first well 110 to be adjacent to the second well 324. Specifically, a lower surface of the third well 322 may be positioned coplanar with a lower surface of the second well 324. A side surface of the third well 322 may be adjacent to a side surface of the second well 324. A conductivity type of the third well 322 may be different from that of the second well 324 and may be identical to that of the first well 110. For example, when the second well 324 is a p-type well, the third well 322 may be an n-type well and the first well 110 may be an n-type well, but the present inventive concepts are not limited thereto.

The fourth well 326 may be disposed in the other side of the first gate structure 360a and the second gate structure 360b and may be formed in the first well 110 to be adjacent to the second well 324. Specifically, a lower surface of the fourth well 326 may be positioned coplanar with the lower surface of the second well 324. A side surface of the fourth well 326 may be adjacent to the side surface of the second well 324. A conductivity type of the fourth well 326 may be different from that of the second well 324 and may be identical to that of the first well 110. For example, when the second well 324 is a p-type well, the fourth well 326 may be an n-type well, but the present inventive concepts are not limited thereto.

The fifth well 335 may be positioned between the first gate structure 360a and the second gate structure 360b and may be formed in the second well 324. A conductivity type of the fifth well 335 may be identical to that of the second well 324 and may be different from that of the first well 110. For example, when the second well 324 is a p-type well, the fifth well 335 may be a p-type well and the first well 110 may be an n-type. However, the present inventive concepts are not limited thereto.

A concentration of an impurity contained in the fifth well 335 may be higher than that of an impurity contained in the second well 324. During the operation of the semiconductor device according to the example embodiment, the fifth well 335 may be used as a base region of a pNPN transistor, but the present inventive concepts are not limited thereto.

The first electrode 374 may be disposed on the fifth well and may be electrically connected to the fifth well 335. For example, the first electrode 374 may be connected to a common base region of the first transistor TR1 and the second transistor TR2, but the present inventive concepts are not limited thereto. In addition, the first electrode 374 may be connected to aground, but the present inventive concepts are not limited thereto.

The sixth well 333 may be positioned between the first gate structure 360a and the fifth well 335 and may be formed in the second well 324. The sixth well 333 may be adjacent only to the second well 324, while being spaced apart from the first well 110. A conductivity type of the sixth well 333 may be different from that of the fifth well 335. For example, when the fifth well 335 is a p-type well, the sixth well 333 may be an n-type well, but the present inventive concepts are not limited thereto.

A concentration of an impurity contained in the sixth well 333 may be higher than that of an impurity contained in the second well 324. During an operation of the semiconductor device according to the example embodiment of the present inventive concepts, the sixth well 333 may be used as a source region of the first transistor TR1, for example, but the present inventive concepts are not limited thereto.

The second electrode 373 may be disposed on the sixth well 333 and may be electrically connected to the sixth well 333. For example, the second electrode 373 may be connected to a source terminal of the first transistor TR1, but the present inventive concepts are not limited thereto.

The seventh well 337 may be positioned between the second gate structure 360b and the fifth well 335 and may be formed in the second well 324. The seventh well 337 may be adjacent only to the second well 324, while being spaced apart from the first well 110. A conductivity type of the seventh well 337 may be different from that of the fifth well 335. For example, when the fifth well 335 is a p-type well, the seventh well 337 may be an n-type well, but the present inventive concepts are not limited thereto.

A concentration of an impurity contained in the seventh well 337 may be higher than that of an impurity contained in the second well 324. During the operation of the semiconductor device according to the example embodiment of the present inventive concepts, the seventh well 337 may be used as a source region of the second transistor TR2, for example, but the present inventive concepts are not limited thereto.

The eighth well 331 may be formed to be overlapped with the third well 322. Specifically, the eighth well 331 may be overlapped with an upper portion of the third well 322. In addition, an upper portion of the second well 324 may be partially overlapped with the eighth well 331. The eighth well 331 may be disposed in one side of the first gate structure 360a. A conductivity type of the eighth well 331 may be identical to that of the third well 322. For example, when the third well 322 is an n-type well, the eighth well 331 may be an n-type well. However, a concentration of an impurity contained in the eighth well 331 may he higher than that of an impurity contained in the third well 322. During an operation of the semiconductor device according to the example embodiment, the eighth well 331 may be used as a drain region, for example, but the present inventive concepts are not limited thereto.

The third electrode 372 may be disposed on the eighth well 331 and may be electrically connected to the eighth well 331. For example, the third electrode 372 may be connected to a drain terminal of the first transistor TR1, but the present inventive concepts are not limited thereto.

The ninth well 339 may be formed to be overlapped with the fourth well 326. Specifically, the ninth well 339 may be overlapped with an upper portion of the fourth well 326. In addition, the upper portion of the second well 324 may be partially overlapped with the ninth well 339. The ninth well 339 may be disposed in the other side of the second gate structure 360b. A conductivity type of the ninth well 339 may be identical to that of the fourth well 326. For example, when the fourth well 326 is an n-type well, the ninth well 339 may be an n-type well. However, a concentration of an impurity contained in the ninth well 339 may be higher than that of an impurity contained in the fourth well 326. During the operation of the semiconductor device according to the example embodiment, the ninth well 339 may be used as a drain region, for example, but the present inventive concepts are not limited thereto.

The tenth well 342 may be disposed below the first gate structure 360a and may be formed in the second well 324 to be adjacent to the sixth well 333. In addition, the tenth well 342 may be spaced apart from the eighth well 331. The tenth well 342 may be formed in a portion of a channel disposed below the first gate structure 360a. The tenth well 342 may be overlapped with only a portion of the first gate structure 360a. That is, the tenth well 342 may be only disposed below a portion of the first gate structure 360a.

The tenth well 342 may be formed deeper than the sixth well 333. A conductivity type of the tenth well 342 may be different from that of the sixth well 333. In addition, the conductivity type of the tenth well 342 may be identical to that of the second well 324. For example, when the second well 324 is a p-type well, the tenth well 342 may be a p-type well.

A concentration of an impurity contained in the tenth well 342 may be higher than that of an impurity contained in the second well 324. In addition, the concentration of an impurity contained in the tenth well 342 may be higher than that of an impurity contained in the sixth well 333. Accordingly, a flow of electrons introduced into the sixth well 333 may be formed in the circumference of the tenth well 342 having an impurity concentration higher than those in the surroundings thereof or may be formed below the tenth well 342.

The first device isolation layer 354 may be formed in the tenth well 342. Specifically, the first device isolation layer 354 may be formed below the first gate structure 360a to be overlapped with the first gate structure 360a. The first device isolation layer 354 may be formed only below the first gate structure 360a. In addition, the first device isolation layer 354 may be formed only in the tenth well 342, but the present inventive concepts are not limited thereto.

The first device isolation layer 354 may be formed deeper than the sixth well 333. That is, a lower surface of the first device isolation layer 354 may be lower than a lower surface of the sixth well 333. The first device isolation layer 354 may be spaced apart from the eighth well 331.

The eleventh well 344 ma be disposed below the second gate structure 360b and may be formed to be spaced apart from the ninth well 339 while being adjacent to the seventh well 337. A conductivity type of the eleventh well 344 may be different from that of the seventh well 337. The second device isolation layer 356 may be formed in the eleventh well 344. The eleventh well 344 and the second device isolation layer 356 may be formed substantially, identically to the tenth well 342 and the first device isolation layer 354, respectively. The eleventh well 344 and the second device isolation layer 356 may be disposed to be symmetrical to the tenth well 342 and the first device isolation layer 354, respectively, with respect to the fifth well 335.

Referring to FIG. 14, the semiconductor device 31 according to the example embodiment of the present inventive concepts may include a first transistor TR1 and a second transistor TR2, the first transistor TR1 and the second transistor TR2 being operated as ESD devices. Hereinafter, a description will be made based on the first transistor TR1.

The first transistor TR1 may include the first gate structure 360a, and the eighth well 331 disposed in one side of the first gate structure 360a may be operated as a drain region and the sixth well 333 may be operated as a source region. High voltage ESD may be introduced into the drain region.

The first transistor TR1 according to the present inventive concepts may form an isolated STI region in gate and source regions. The isolated STI region may vertically form a deep current path.

In addition, the tenth well 342 may be formed below the first gate structure 360a and the conductivity type of the tenth well 342 may be different from that of the source region or the drain region. Moreover, the tenth well 342 may be disposed to be adjacent to the source region, while being spaced apart from the drain region, but the present inventive concepts are not limited thereto. Further, the first device isolation layer 354 may be formed in the tenth well 342. By doing so, a path of electrons moving from the source region to the drain region may be directed more downward and through STI interfacial effects and the like, the concentration of a current flow on a channel interface may be mitigated or prevented.

Furthermore, deep n-type wells (NW) such as the third well 322 and the fourth well 326 may be periodically formed to form a new current path. By doing so, the current path may be further deeply formed, such that existing current characteristics may be improved.

In addition, the fifth well 335 may be disposed to be adjacent to the sixth well 333 operated as the source region, and a conductivity type of the fifth well 335 may be different from that of the sixth well 333, whereby the parasitic transistor pNPN may be independently operated. By doing so, uniformity in the current flow may be improved.

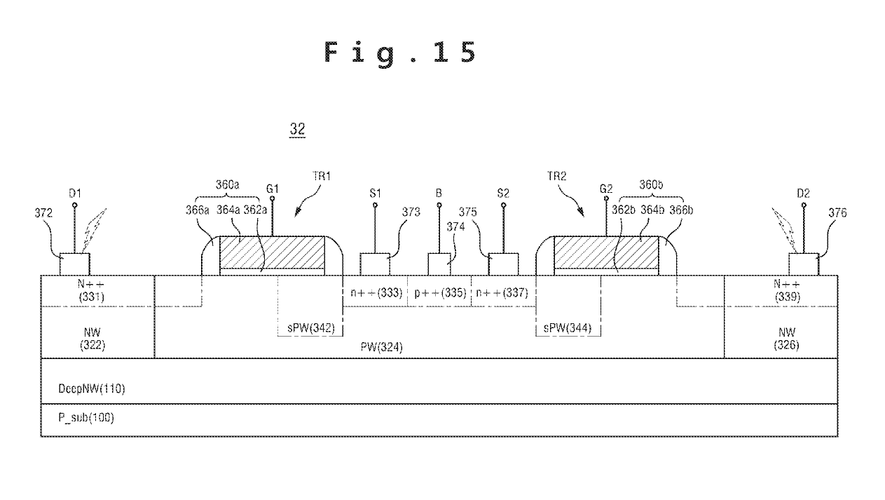

FIG. 15 is a cross-sectional view of a semiconductor device according to a tenth example embodiment of the present inventive concepts. For convenience of explanation, an overlapped description regarding elements identical to those of the foregoing embodiment will be omitted, and differences will be mainly explained hereinafter.

Referring to FIG. 15, a semiconductor device 32 according to the tenth example embodiment of the present inventive concepts may be formed and operated in a manner substantially identical to that of the semiconductor device 31 according to the ninth example embodiment of the present inventive concepts described with reference to FIG. 13.

However, in the semiconductor device 32 according to the tenth example embodiment of the present inventive concepts, the first device isolation layer 354 may not be formed. As the first device isolation layer 354 is not formed, a Channel region of the first transistor TR1 may be operated.

By doing so, while the semiconductor device 31 according to the ninth example embodiment of the present inventive concepts are usable only as a gate-grounded (GG) type device, the semiconductor device 32 according to the tenth example embodiment of the present inventive concepts may be used as agate-coupled (GC) type device as well as being used as the GG type device.

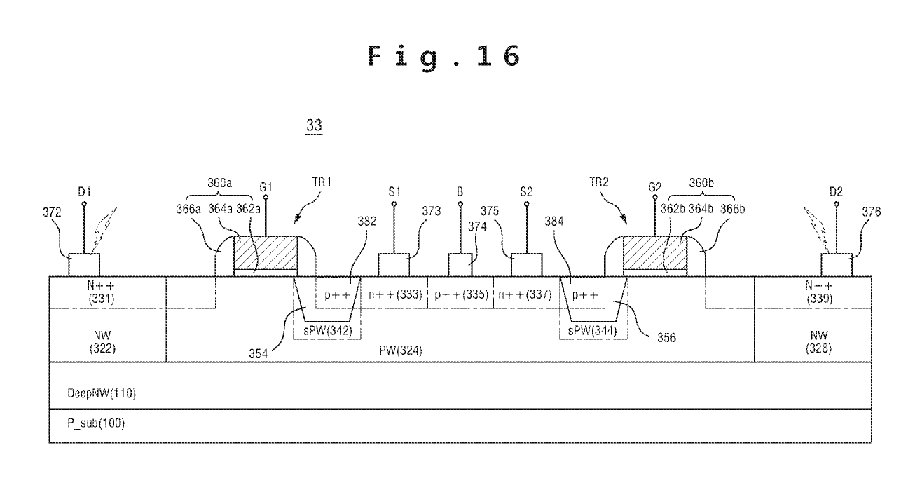

FIG. 16 is a cross-sectional view of a semiconductor device according to an eleventh example embodiment of the present inventive concepts. For convenience of explanation, an overlapped description regarding elements identical to those of the foregoing embodiment will be omitted, and differences will be mainly explained hereinafter.

Referring to FIG. 16, a semiconductor device 33 according to the eleventh example embodiment of the present inventive concepts may be formed and operated in a manner substantially identical to that of the semiconductor device 31 according to the ninth example embodiment of the present inventive concepts described with reference to FIG. 14.

However, the semiconductor device 33 according to the eleventh example embodiment of tile present inventive concepts may further include a twelfth well 382. The twelfth well 382 may be formed in the tenth well 342. In addition, the twelfth well 382 may be overlapped with the first device isolation layer 354.

Specifically, an upper portion of the first device isolation layer 354 may be partially overlapped with the twelfth well 382. In addition, the twelfth well 382 may be overlapped with a portion of the tenth well 342. The twelfth well 382 may be disposed in the other side of the first gate structure 360a. That is, the twelfth well 382 and the eighth well 331 may be disposed in both sides of the first gate structure 360a. Moreover, the twelfth well 382 may be positioned between the first gate structure 360a and the sixth well 333 and may be disposed not to be overlapped with the first gate structure 360a. However, the present inventive concepts are not limited thereto.

A conductivity type of the twelfth well 382 may be identical to that of the tenth well 342. In addition, the conductivity type of the twelfth well 382 may be different from that of the sixth well 333. For example, when the tenth well 342 is a p-type well, the twelfth well 382 may be a p-type well. A concentration of an impurity contained in the twelfth well 382 may be higher than that of an impurity contained in the tenth well 342. The twelfth well 382 may be formed by additionally doping a p-type impurity into the first device isolation layer 354 exposed, but the present inventive concepts are not limited thereto.

By doing so, a path of electrons moving from the source region to the drain region may be directed more downward and due to STI interfacial effects and the formation of a new current path, the concentration of a current flow on a channel interface may be mitigated or prevented.

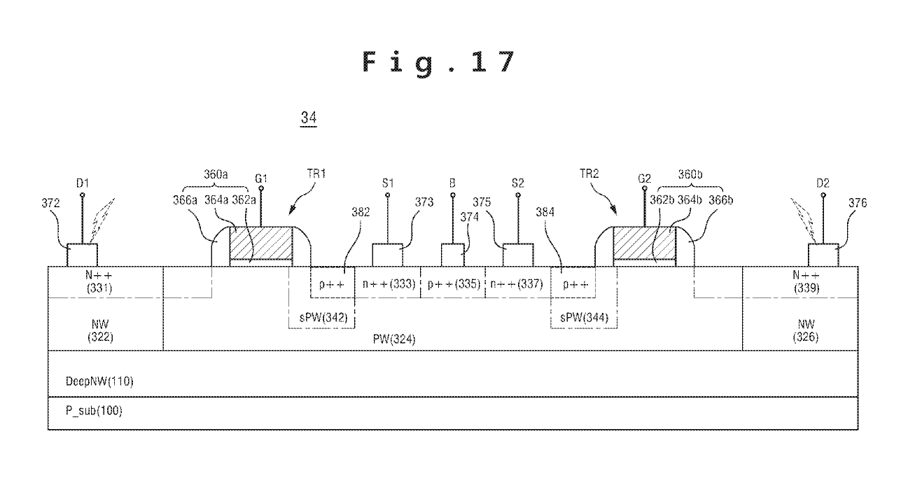

FIG. 17 is across-sectional view of a semiconductor device according to a twelfth example embodiment of the present inventive concepts. For convenience of explanation, an overlapped description regarding elements identical to those of the foregoing embodiment will be omitted, and differences will be mainly explained hereinafter.

Referring to FIG. 17, a semiconductor device 34 according to the twelfth example embodiment of the present inventive concepts may be formed and operated in a manner substantially identical to that of the semiconductor device 32 according to the tenth example embodiment of the present inventive concepts described with reference to FIG. 4.

However, the semiconductor device 34 according to the twelfth example embodiment of the present inventive concepts may further include the twelfth well 382. Consequently, the first device isolation layer 354 may not be formed in the tenth well 342, and only the twelfth well 382 may be formed therein.

Specifically, the twelfth well 382 may be formed in the tenth well 342. Specifically, an upper portion of the tenth well 342 may be partially overlapped with the twelfth well 382. The twelfth well 382 may be disposed in the other side of the first gate structure 360a. That is, the twelfth well 382 and the eighth well 331 may be disposed in both sides of the first gate structure 360a. Moreover, the twelfth well 382 may be positioned between the first gate structure 360a and the sixth well 333 and may be disposed not to be overlapped with the first gate structure 360a.

The twelfth well 382 may be formed by additionally doping a p-type impurity into the tenth well 342 exposed. The conductivity type of the twelfth well 382 may be identical to that of the tenth well 342. For example, when the tenth well 342 is a p-type well, the twelfth well 382 may be a p-type well. In addition, the concentration of an impurity contained in the twelfth well 382 may be higher than that of an impurity contained in the tenth well 342. By doing so, a path of electrons moving from the source region to the drain region may be formed downwardly of the twelfth well 382 and the tenth well 342, such that the concentration of a current flow on a channel interface may be mitigated or prevented.

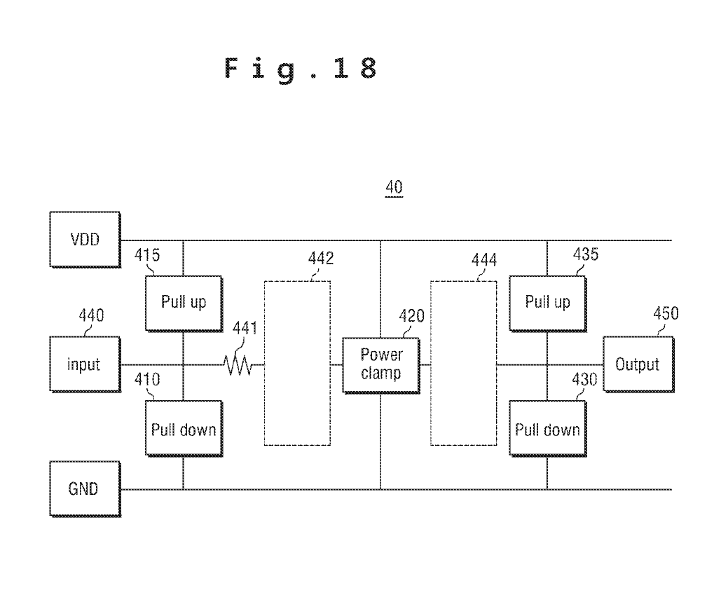

FIG. 18 is a block diagram illustrating an ESD protection circuit including a semiconductor device according to some example embodiments of the present inventive concepts.

Referring to FIG. 18, a semiconductor device 40 according to some example embodiments of the present inventive concepts may include ESD protection circuits 410, 415, 420, 430 and 435, logic circuits 442 and 444, an input terminal 440, and an output terminal 450.

The input terminal 440 may transmit an input signal to the logic circuits 442 and 444 included in the semiconductor device, and the output terminal 450 may transmit a signal output from the logic circuits 442 and 444 to an external device. Specifically, a signal entered through the input terminal 440 may pass through a resistor 441 and may be transmitted to the logic circuits 442 and 444. The resistor 441 may serve as a buffer, but the present inventive concepts are not limited thereto. The resistor 441 may be omitted. The input terminal 440 may be connected to an input pad (not shown) and similarly, the output terminal 450 may be connected to an output pad (not shown).

The logic circuits 442 and 444 may receive the input signal applied to the input terminal 440 to generate an output signal based on the input signal. The logic circuits 442 and 444 may include various transistors TR, a resistor R, a capacitor C and the like. The logic circuits 442 and 444 may generate specific outputs with respect to specific inputs. For example, the logic circuits 442 and 444 may perform a practical operation desired by a user. The logic circuits 442 and 444 may include a first logic circuit 442 and a second logic circuit 444, the first logic circuit 442 and the second logic circuit being integrally formed with each other.

The ESD protection circuits may include pull-up circuits 415 and 435, pull-down circuits 410 and 430, and a power clamp circuit 420. The semiconductor devices 11 to 14, 21 to 24, and 31 to 34 according to some example embodiments of the present inventive concepts may be used in the pull-up circuits 415 and 435, the pull-down circuits 410 and 430, and the power clamp circuit 420. [2191 In the case that a level of the input signal is outside of a desired (or, alternatively a predetermined) range, the ESD protection circuits may adjust the level of the input signal. For example, when a high-voltage- input signal is temporarily applied, the ESD protection circuits may lower the level of the input signal. The desired (or, alternatively a predetermined) range corresponds to a range within which the logic circuits 442 and 444 included in the semiconductor device can be normally operated.

The pull-down circuits 410 and 430 of the ESD protection circuits may include a gate-grounded NMOS (GGNMOS), and the pull-up circuits 415 and 435 of the ESD protection circuits may include a gate-grounded PMOS (GGPMOS). The power clamp circuit 420 may include a gate-coupled NMOS (GCNMOS). However, the present inventive concepts are not limited thereto.

The pull-up circuit 415 or 435 may be disposed between the input terminal 440 and a power source VDD or between the output terminal 450 and the power source VDD. The pull-down circuit 410 or 430 may be disposed between the input terminal 440 and aground GND or between the output terminal 450 and the ground GND. The power clamp circuit 420 may be disposed between the power source VDD and the ground GND and may be connected to the logic circuits 442 and 444.

Specifically, the pull-up circuits 415 and 435 may receive negative (−) ESD equal to or less than a voltage of the ground GND from the input terminal 440 and discharge the ESD to the power source VDD or discharge the ESD to the ground GND through the power clamp circuit 420. Alternatively, the pull-down circuits 410 and 430 may receive positive (+) ESD equal to or more than a voltage of the power source VDD and discharge the ESD to the ground GND or discharge the ESD to the power source VDD through the power clamp circuit 420. However, the present inventive concepts are not limited thereto.

By doing so, the semiconductor device according to the example embodiments of the present inventive concepts may protect the logic circuits 442 and 444 from the ESD applied from the input terminal 440 through the ESD protection circuits 410, 415, 420, 430 and 435. The arrangements of the power clamp circuit 420, the pull-up circuits 415 and 435, and the pull-down circuits 410 and 430 disposed between the logic circuits 442 and 444 are not limited to those illustrated in FIG. 18.

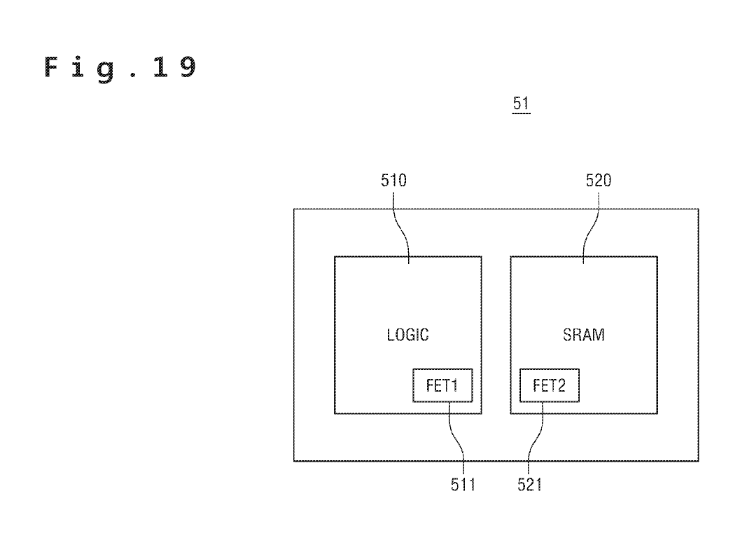

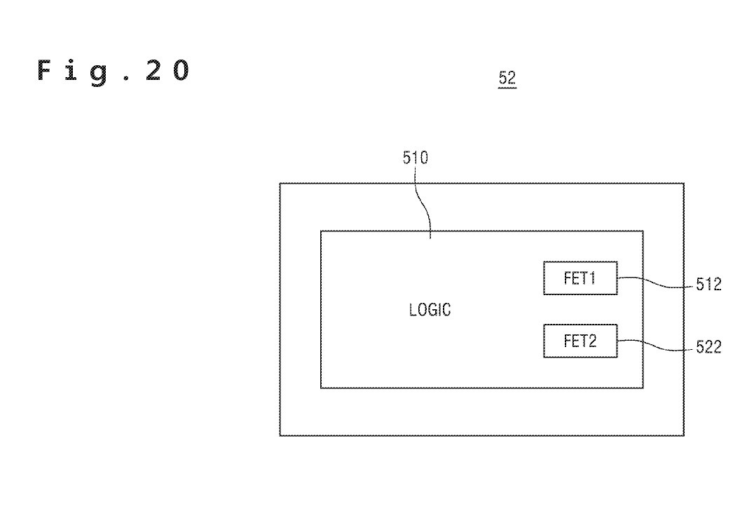

FIG. 19 is a view illustrating a semiconductor device according to some other example embodiments of the present inventive concepts. FIG. 20 is a view illustrating a semiconductor device according to some other example embodiments of the present inventive concepts. Hereinafter, differences with the foregoing example embodiments will be mainly described.

Referring to FIG. 19 first, a semiconductor device 51 according to some other example embodiments of the present inventive concepts may include a logic region 510 and an SRAM forming region 520. A first transistor 511 may be disposed in the logic region 510 and a second transistor 521 may be disposed in the SRAM forming region 520. FIG. 19 illustrates the logic region 510 and the SRAM forming region 500 by way of example, but example embodiments of the present inventive concepts are not limited thereto. For example, the present inventive concepts may also be applied to the logic region 510 and a memory forming region for forming other memories (e.g., dynamic random access memory (DRAM), magnetic random access memory (MRAM), resistive random access memory (RRAM), phase-change random access memory (PRAM), etc.)

Next, referring to FIG. 20, a semiconductor device 52 according to some other example embodiments of the present inventive concepts may include the logic region 510, but different third and fourth transistors 512 and 522 may be disposed in the logic region 510. Although not separately illustrated, the different third and fourth transistors 512 and 522 may also be disposed in the SRAM forming region.

Here, the first transistor 511 may be one of the semiconductor devices 11 to 14, 21 to 51, and 31 to 34 according to the foregoing example embodiments of the present inventive concepts, and the second transistor 521 may be another one of the semiconductor devices 11 to 14, 21 to 51, and 31 to 34 according to the foregoing example embodiments of the present inventive concepts. For example, the first transistor 511 may be the semiconductor device 11 of FIG. 2 and the second transistor 521 may be the semiconductor device 21 of FIG. 8.

Meanwhile, the third transistor 412 may be one of the semiconductor devices 11 to 14, 21 to 51, and 31 to 34 according to the foregoing example embodiments of the present inventive concepts, and the second transistor 422 may be another one of the semiconductor devices 11 to 14, 21 to 51, and 31 to 34 according to the foregoing example embodiments of the present inventive concepts.

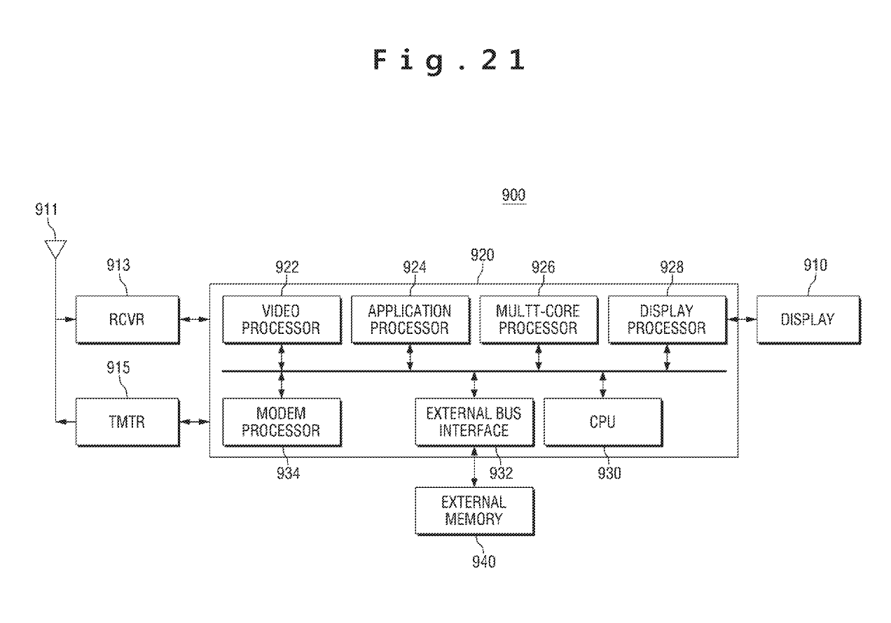

FIG. 21 is a block diagram illustrating a wireless communications device including the semiconductor device according to the example embodiments of the present inventive concepts.

Referring to FIG. 21, a wireless communication device 900 may be a cellular phone, a smart phone terminal, a handset, a personal digital assistant (PDA), a laptop computer, a video game unit, or another type of device. The device 900 may use, for example, code division multiple access (CDMA), time division multiple access (TDMA) such as a global system (GSM) for mobile communications, or other wireless communication standards.

The device 900 may provide bi-directional communications through a reception path and a transmission path. Signals transmitted by one or more base stations on the reception path may be received through an antenna 911 or may be provided to a receiver (RCVR) 913. The receiver 913 may perform conditioning and digitalization of the received signal and provide samples to a digital section 920 for additional processing. On the transmission path, a transmitter (TMTR) 915 may receive data transmitted from the digital section 920, perform processing and conditioning of the data, and generate a modulated signal. The modulated signal may be transmitted to one or more base stations through the antenna 911.

The digital section 920 may be implemented as one or more digital signal processors (DSP), a microprocessor, a reduced instruction set computer (RISC) and the like. Further, the digital section 920 may be fabricated on one or more application-specific integrated circuits (ASIC) or other types of integrated circuits (IC).

The digital section 920 may include, for example, various processing and interface units such as a modem processor 934, a video processor 922, an application processor 924, a display processor 928, a controller/multi-core processor 926, a central processing unit 930, and an external bus interface (EBI) 932.

The video processor 922 may perform processing on graphics applications. In general, the video processor 922 may include an optional number of processing units or modules for an optional set of graphic operations. A specific part of the video processor 922 may be implemented as firmware and/or software. For example, a control unit may be implemented as firmware and/or software modules (e.g., procedures, functions and the like) for performing the above-described functions. Firmware and/or software codes may be stored in a memory, or may be executed by a processor (e.g., the multi-core processor 926). The memory may be implemented within or outside the processor.

The video processor 922 may implement a software interface such as open graphic library (OpenGL), Direct3D or the like. The central processing unit 930 may perform a series of graphic processing operations together with the video processor 922. The controller/multi-core processor 926 may include at least two cores and allocate workloads to the two cores (depending on the workloads which the controller multi-core processor 926 needs to process) to thereby simultaneously process the corresponding workloads.

Although the application processor 924 is illustrated as a single component included in the digital section 920, the present inventive concepts are not limited thereto. In some example embodiments of the present inventive concepts, the digital section 920 may be implemented to be integrated into a single application processor 924 or an application chip.

The modem processor 934 may perform necessary operations in a process of transferring data between the digital section 920 and the receiver 913 and between the digital section 920 and the transmitter 915. The display processor 928 may perform operations for driving the display 910.

The semiconductor devices 11 to 14, 21 to 24, and 31 to 34 according to the example embodiments of the present inventive concepts as described above may be used as cache memories or buffer memories used for operations of the processors 922, 924, 926, 928, 930, and 934 illustrated.

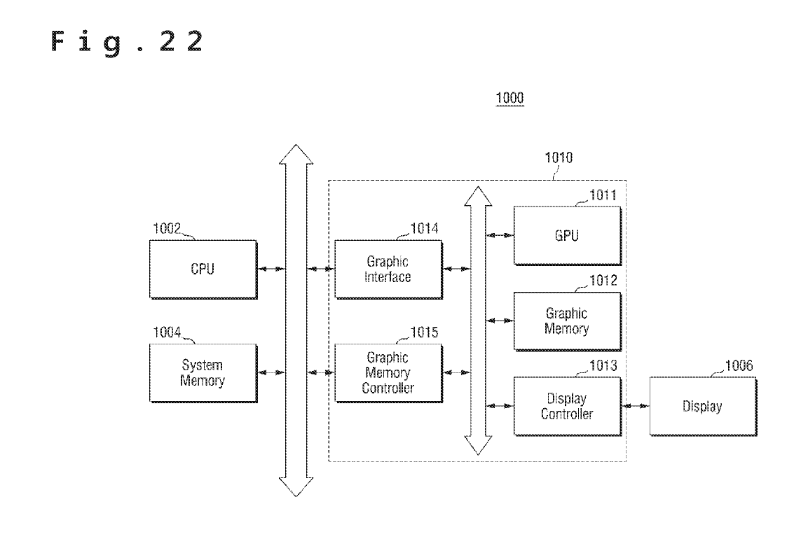

Next, referring to FIG. 22, a computing system including the semiconductor device according to example embodiments of the present inventive concepts will be described.

FIG. 22 is a block diagram of a computing system including the semiconductor device according to the example embodiments of the present inventive concepts.

Referring to FIG. 22, a computing system 1000 according to an example embodiment of the present inventive concepts may include a central processing unit (CPU) 1002, a system memory 1004, a graphic system 1010, and a display 1006.

The central processing unit 1002 may perform operations for driving the computing system 1000. The system memory 1004 may be configured to store data therein. The system memory 1004 may store data that is processed by the central processing unit 1002. The system memory 1004 may serve as an operating memory of the central processing unit 1002. The system memory 1004 may include one or more volatile memories such as a DDR SDRAM (Double Data Rate Static DRAM) or SDR SDRAM (Single Data Rate SDRAM), and/or one or more non-volatile memories such as EEPROM (Electrical Erasable Programmable ROM) or a flash memory. One of the semiconductor devices 11 to 14, 21 to 24, and 31 to 34 according to the example embodiments of the present inventive concepts as described above may be adopted as a component of the system memory 1004.

The graphic system 1010 may include a graphic processing unit (GPU) 1011, a graphic memory 1012, a display controller 1013, a graphic interface 1014, and a graphic memory controller 1015.

The graphic processing unit 1011 may perform graphic operations for the computing system 1000. Specifically, the graphic processing unit 1011 may assemble primitives including at least one vertex, and may perform rendering using the assembled primitives.

The graphic memory 1012 may store graphic data that is processed by the graphic processing unit 1011 or graphic data provided to the graphic processing unit 1011. Alternatively, the graphic memory 1012 may serve as an operating memory of the graphic processing unit 1011. One of the semiconductor devices 1 to 6 according to the example embodiments of the present inventive concepts as described above may be adopted as a component of the graphic memory 1012.

The display controller 1013 may control the display 1006 to display rendered image frames.

The graphic interface 1014 may perform interfacing between the central processing unit 1002 and the graphic processing unit 1011. The graphic memory controller 1015 may provide a memory access between the system memory 1004 and the graphic processing unit 1011.

Although not specifically illustrated in FIG. 22, the computing system 1000 may further include one or more input devices such as buttons, a touch screen, and a microphone, and/or one or more output devices such as speakers. The computing system 1000 may further include an interface device for exchanging data with an external device by wire or wirelessly. The interface device may include, for example, an antenna or a wired/wireless transceiver.

According to embodiments, the computing system 1000 may be an optional computing system such as a mobile phone, a smart phone, a personal digital assistant (PDA), a desktop computer, a notebook computer, a tablet or the like.

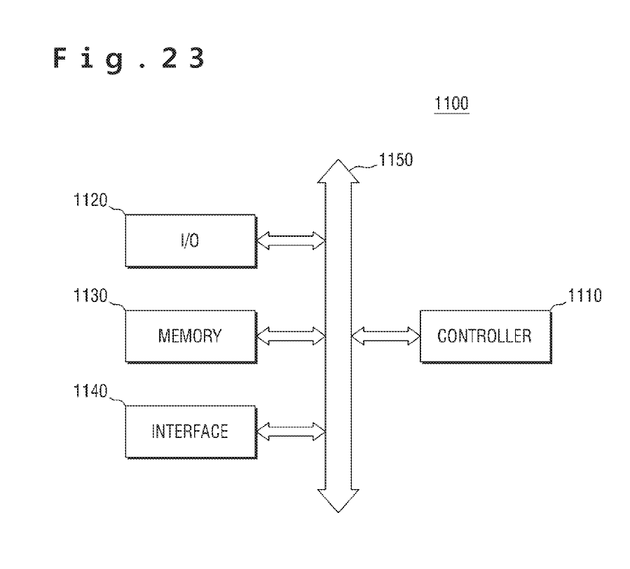

Next, referring to FIG. 23, an electronic system including the semiconductor device according to the example embodiments of the present inventive concepts will be described.

FIG. 23 is a block diagram of an electronic system including the semiconductor device according to the example embodiments of the present inventive concepts.

Referring to FIG. 23, an electronic system 1100 according to an example embodiment of the present inventive concepts may include a controller 1110, an input/output device (I/O) 1120, a memory device 1130, an interface 1140 and a bus 1150. The controller 1110, the input/output device (I/O) 1120, the memory device 1130, and/or the interface 1140 may be coupled to each other through the bus 1150. The bus 1150 may correspond to a path through which data is transferred.

The controller 1110 may include at least one of a microprocessor, a digital signal processor, a microcontroller and logic devices capable of performing similar functions thereto. The input/output device (I/O) 1120 may include a keypad, keyboard, a display and the like.

The memory device 1130 may store data and/or a command or the like therein. The interface 1140 may transmit data to communication networks and receive data from the communication networks. The interface 1140 may have a wired or wireless form. For example, the interface 1140 may include an antenna, a wired/wireless transceiver and the like.

Although not illustrated, the electronic system 1100 may be an operating memory for improving operations of the controller 1110 and may further include a high speed dynamic random access memory (DRAM) and/or static random access memory (SRAM) or the like. In this case, one of the semiconductor devices 10 to 15 and 20 to 25 according to the example embodiments of the present inventive concepts as described above may be adopted as the operating memory. In addition, one of the semiconductor devices 10 to 15 and 20 to 25 according to the example embodiments of the present inventive concepts as described above may be provided within the memory device 1130 or may be provided as parts of the controller 1110, the input/output device (I/O) 1120 and the like.

The electronic system 1100 may be applied to personal digital assistants (PDA), portable computers, web tablets, wireless phones, mobile phones, digital music players, memory cards, or all electrical products capable of transmitting and/or receiving information in wireless environments.

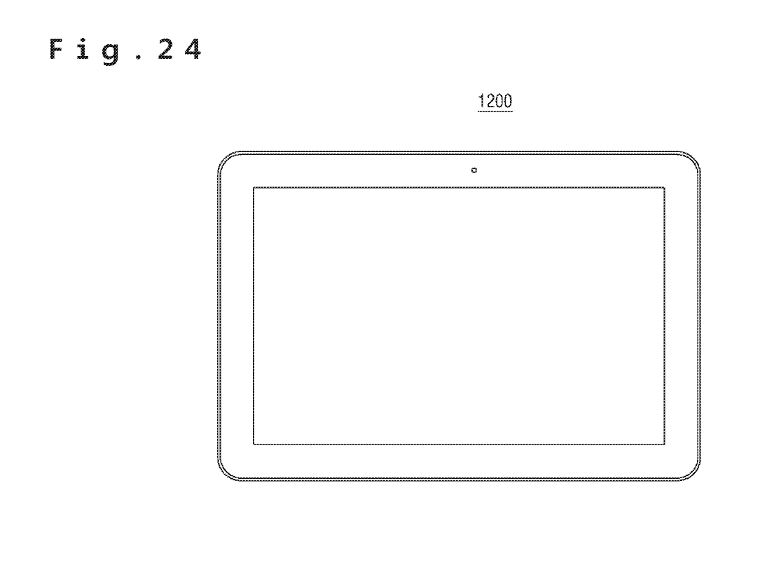

FIG. 24 through FIG. 26 are example semiconductor systems to which the semiconductor device according to some example embodiments of the present inventive concepts are applicable.

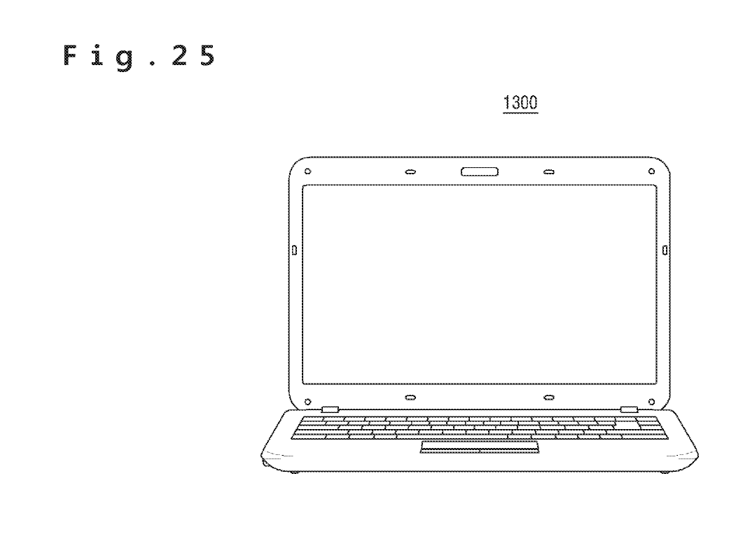

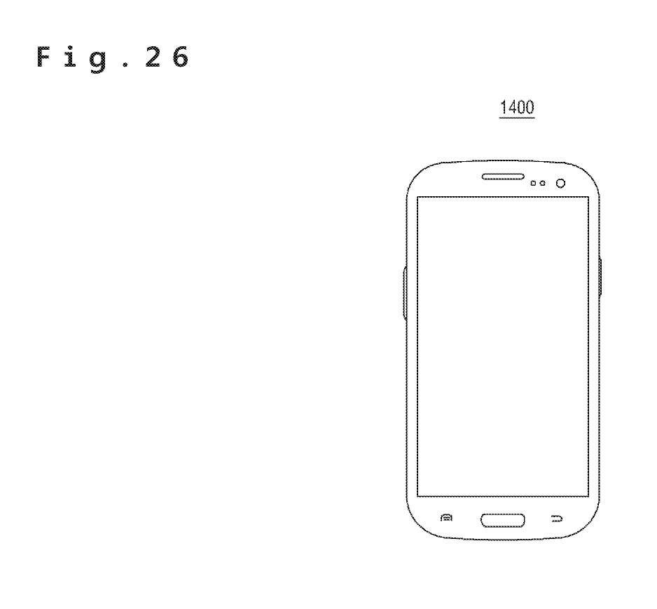

FIG. 24 is a view illustrating a tablet PC 1200, FIG. 25 is a view illustrating a laptop computer 1300, and FIG. 26 is a view illustrating a smartphone 1400. At least one of the semiconductor devices 11 to 14, 21 to 24, and 31 to 34 according to the example embodiments of the present inventive concepts may be used in the tablet PC 1200, the laptop computer 1300, the smartphone 1400 and the like.

In addition, it may be apparent to a person having ordinary skill in the art that the semiconductor devices 1 and 2 according to some example embodiments of the present inventive concepts may be applied to other integrated circuit devices (not shown). That is, in the above description, only the tablet PC 1200, the laptop computer 1300, and the smartphone 1400 are exemplified as the electronic system according to the embodiment. However, examples of the electronic system according to the example embodiment are not limited thereto. In some embodiments of the present inventive concepts, the electronic systems may be implemented as computers, UMPC (Ultra Mobile PC), workstations, net-book computers, personal digital assistants (PDA), portable computers, wireless phones, mobile phones, e-books, portable multimedia player (PMP), portable game consoles, navigation devices, black boxes, digital cameras, 3-dimensional televisions, digital audio recorders, digital audio players, digital picture recorders, digital picture players, digital video recorders, digital video players and the like.

While the present inventive concepts has been particularly shown and described with reference to example embodiments thereof, it will be understood by those of ordinary skill in the art that various changes in form and details may be made therein without departing from the spirit and scope of the present inventive concepts as defined by the following claims. It is therefore desired that the present embodiments be considered in all respects as illustrative and not restrictive, reference being made to the appended claims rather than the foregoing description to indicate the scope of the inventive concepts.

What is claimed is:

1. A semiconductor device comprising:
a first well in a substrate;
a gate structure on the first well;
a second well below the gate structure in the first well;
a third well in a first side of the gate structure and in the first well, the third well being adjacent to the second well and having a conductivity type different from that of the second well,
a fourth well overlapped with the third well;
a fifth well in a second side of the gate structure and in the second well;
a sixth well below the gate structure and in the second well, the sixth well being adjacent to the fifth well and having an impurity concentration higher than the impurity concentration of the second well; and
a first device isolation layer overlapped with the second well and disposed farther away from the gate structure than the fifth well.

2. The semiconductor device of claim 1, further comprising:
a second device isolation layer in the sixth well,
wherein the second device isolation layer is formed below the gate structure to be overlapped with the gate structure.

3. The semiconductor device of claim 2, wherein the second device isolation layer is formed deeper than the fifth well.

4. The semiconductor device of claim 2, wherein the second device isolation layer is spaced apart from the fourth well.

5. The semiconductor device of claim 2, further comprising:
an eighth well overlapped with the second device isolation layer and having an impurity concentration higher than the impurity concentration of the sixth well.

6. The semiconductor device of claim 5, wherein the eighth well is not overlapped with the gate structure and is positioned between the gate structure and the fifth well.

7. The semiconductor device of claim 1, further comprising:
an eighth well in the sixth well and having an impurity concentration higher than the impurity concentration of the sixth well.

8. The semiconductor device of claim 1, wherein
the second well has a conductivity type different from that of the first well, and
the fifth well has a conductivity type different from that of the second well.

9. The semiconductor device of claim 1, further comprising:
a seventh well positioned between the first device isolation layer and the fifth well and in the second well,
wherein the seventh well is adjacent to the fifth well and has a conductivity type different from that of the fifth well.

10. The semiconductor device of claim 1, further comprising:
an eleventh well in the first well, the eleventh well being adjacent to the second well and having a conductivity type different from that of the second well; and
a twelfth well in the eleventh well,
wherein the twelfth well is adjacent to the first device isolation layer.

11. A semiconductor device comprising:
a first well in a substrate;
a second well in the first well, the second well having a conductivity type different from that of the first well;
a first gate structure on the second well;
a second gate structure on the second well and spaced apart from the first gate structure;
a third well between the first and second gate structures and in the second well;
a fourth well in a first side of the first and second gate structures and in the second well;
a fifth well n a second side of the first and second gate structures and in the second well;
a sixth well below the first gate structure and spaced apart from the third well while being adjacent to the fourth well, the sixth well having a conductivity type different from that of the fourth well; and
a seventh well below the second gate structure and spaced apart from the third well while being adjacent to the fifth well, the seventh well having a conductivity type different from that of the fifth well.

12. The semiconductor device of claim 11, further comprising:
a first device isolation layer overlapped with the second well and disposed farther away from the first gate structure than the fourth well; and
a second device isolation layer overlapped with the second well and disposed farther away from the second gate structure than the fifth well.

13. The semiconductor device of claim 12, further comprising:
an eighth well between the first device isolation layer and the fourth well and in the second well,
wherein the eighth well is disposed to be adjacent to the fourth well, the eighth well having a conductivity type different from that of the fourth well.

14. The semiconductor device of claim 11, further comprising:
a third device isolation layer in the sixth well; and
a fourth device isolation layer in the seventh well.

15. The semiconductor device of claim 14, further comprising:
a ninth well overlapped with the third device isolation layer and having an impurity concentration higher than that of the sixth well.

16. The semiconductor device of claim 11, further comprising:
a ninth well in the sixth well and having an impurity concentration higher than that of the sixth well.

17. The semiconductor device of claim 11, wherein
each of the third well and the fourth well has a conductivity type different from that of the second well, and
the first well contains an n-type impurity.

18. A semiconductor device comprising:
a first well in a substrate;
a second well in the first well;
a first gate structure on the second well,
a second gate structure on the second well, the second gate structure being spaced apart from the first gate structure;
a third well in a first side of the first and second gate structures and in the first well to be adjacent to the second well, the third well having a conductivity type different from that of the second well,
a fourth well in a second side of the first and second gate structures and in the first well to be adjacent to the second well, the fourth well having a conductivity type different from that of the second well;
a fifth well between the first and second gate structures and in the second well;
a sixth well between the first gate structure and the fifth well, the sixth well having a conductivity type different from that of the fifth well;
a seventh well between the second gate structure and the fifth well, the seventh well having a conductivity type different from that of the fifth well;
an eighth well overlapped with the third well,
a ninth well overlapped with the fourth well;
a tenth well disposed below the first gate structure and spaced apart from the eighth well while being adjacent to the sixth well, the tenth well having a conductivity type different from that of the sixth well; and
an eleventh well disposed below the second gate structure and spaced apart from the ninth well while being adjacent to the seventh well, the eleventh well having a conductivity type different from that of the seventh well.

19. The semiconductor device of claim 18, further comprising:
a first device isolation layer in the tenth well; and
a second device isolation layer in the eleventh well.

20. The semiconductor device of claim 18, further comprising:
a twelfth well in the tenth well and having an impurity concentration higher than in the impurity concentration of the sixth well.
